(19) United States
(12) Patent Application Publication
(10) Pub. No.: US 2025/0230335 A1
(43) Pub. Date: Jul. 17, 2025

(54) ARTICLES HAVING A COATING INCLUDING POLYELECTROLYTES AND A PHOTOCLEAVABLE POLYMER, AND METHODS OF MAKING SAME

(71) Applicant: 3M INNOVATIVE PROPERTIES COMPANY, St. Paul, MN (US)

(72) Inventors: Constantin-Christian A. Voll, St. Paul, MN (US); Brylee David B. Tiu, Minneapolis, MN (US); Daniel J. Schmidt, Woodbury, MN (US)

(21) Appl. No.: 18/701,959

(22) PCT Filed: Nov. 21, 2022
(86) PCT No.: PCT/IB2022/061216

§ 371 Date: Apr. 17, 2024

Related U.S. Application Data
(60) Provisional application No. 63/292,473, filed on Dec. 22, 2021.
(60) Provisional application No. 63/355,161, filed on Jun. 24, 2022.

(51) Int. Cl. C09D 133/10

(52) U.S. Cl. CPC C09D 133/10

(57) ABSTRACT

Articles (100) are provided including a substrate (110) and a coating (120) disposed on a major surface (112) of the substrate. The coating includes one or more polyelectrolytes, a photocleavable polymer, and optionally a light absorbing material. The light absorbing material is present and/or the photocleavable polymer includes one or more polymers of any of specific formulas. Methods of making an article are additionally provided. The method includes applying a coating to a major surface of a substrate. Optionally, the method includes selectively irradiating the article with light and rinsing the irradiated article to remove portions of the coating to provide an article in which the coating is present on the substrate in a pattern.

### FIELD

The present disclosure generally relates to articles having coatings containing photocleavable polymers.

### SUMMARY

In a first aspect, an article is provided. The article comprises a substrate and a coating disposed on a major surface of the substrate. The coating comprises one or more polyelectrolytes, a photocleavable polymer, and optionally a light absorbing material. The light absorbing material is present and/or the photocleavable polymer includes a polymer of any of Formula I, Formula II, and/or Formula III:

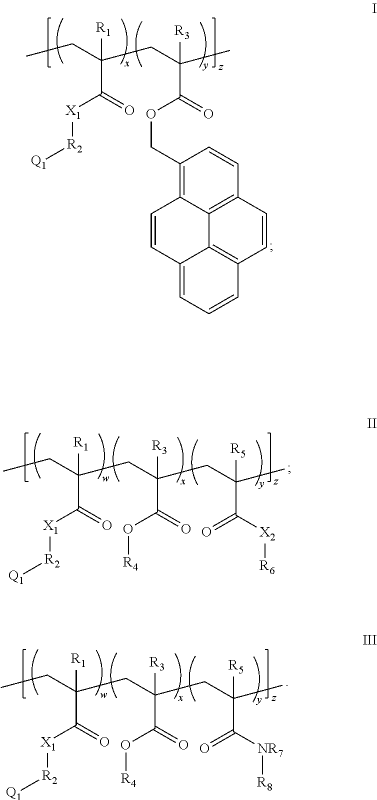

R₁ is independently selected from H or methyl; R₂ is independently selected from an alkylene group or a heteroalkylene group; Q₁ is independently selected from an amino group selected from a primary amino group, secondary amino group, tertiary amino group, quaternary amino group, or a salt thereof, R₃ is independently selected from H or methyl; X₁ is O or NH; R₄ is independently selected from a photocleavable group selected from the group consisting of arylmethyl, coumarin-4-ylmethyl, nitroaryl, and arylcarbonylmethyl; R₅ is independently selected from H or methyl; X₂ is O or NH; R₆ is independently selected from OH or a heteroalkylene group; R₇ is H or methyl; R₈ is H or methyl; and each of w, x, y, and z is a designation of a repeat unit.

In a second aspect, a method of making an article is provided. The method comprises applying a coating to a major surface of a substrate. The coating comprises a photocleavable polymer, and optionally a light absorbing material, wherein the light absorbing material is present and/or the photocleavable polymer includes a polymer of any of Formula I, Formula II, and/or Formula III:

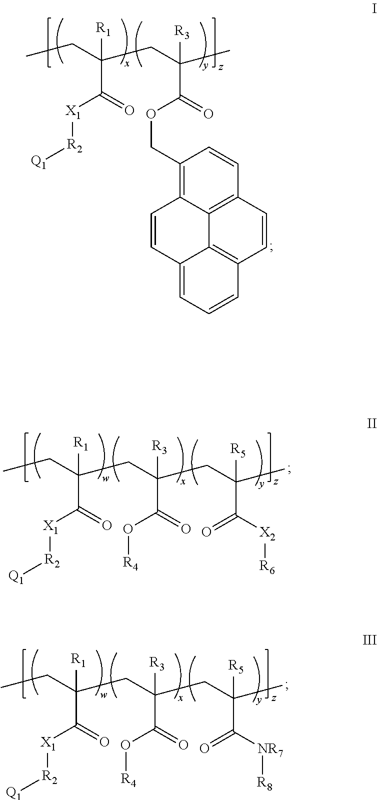

R₁ is independently selected from H or methyl; R₂ is independently selected from an alkylene group or a heteroalkylene group; Q₁ is independently selected from an amino group selected from a primary amino group, secondary amino group, tertiary amino group, quaternary amino group, or a salt thereof, R₃ is independently selected from H or methyl; X₁ is O or NH; R₄ is independently selected from a photocleavable group selected from the group consisting of arylmethyl, coumarin-4-ylmethyl, nitroaryl, and arylcarbonylmethyl; R₅ is independently selected from H or methyl; X₂ is O or NH; R₆ is independently selected from OH or a heteroalkylene group; R₇ is H or methyl; R₈ is H or methyl; and each of w, x, y, and z is a designation of a repeat unit.

The above summary of the present disclosure is not intended to describe each disclosed embodiment or every implementation of the present disclosure. The description that follows more particularly exemplifies illustrative embodiments. In several places throughout the application, guidance is provided through lists of examples, which examples may be used in various combinations. In each instance, the recited list serves only as a representative group and should not be interpreted as an exclusive list.

### BRIEF DESCRIPTION OF THE DRAWINGS

FIG. 1 is a schematic cross-sectional view of an exemplary article according to the present disclosure.

FIG. 2 is a schematic cross-sectional view of another exemplary article according to the present disclosure.

FIG. 3 is a photograph of an exemplary article prepared according to the present disclosure.

While the above-identified figures set forth various embodiments of the disclosure, other embodiments are also contemplated, as noted in the description. In all cases, this disclosure presents the invention by way of representation and not limitation. The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

### Glossary

The thickness of a layer (coating, substrate, adhesive, etc.) should be understood to be its smallest dimension. It is generally referred to as the “z” dimension and refers to the distance between the major surfaces of the layer.

The term “backbone” refers to the main continuous chain of a polymer.

The term “aliphatic” refers to C1-C40, suitably C1-C30, straight or branched chain alkenyl, alkyl, or alkynyl which may or may not be interrupted or substituted by one or more heteroatoms such as O, N, or S.

The term “cycloaliphatic” refers to cyclized aliphatic C3-C30, suitably C3-C20, groups and includes those interrupted by one or more heteroatoms such as O, N, or S.

The term “alkyl” refers to a monovalent group that is a radical of an alkane and includes straight-chain, branched, cyclic, and bicyclic alkyl groups, and combinations thereof, including both unsubstituted and substituted alkyl groups. Unless otherwise indicated, the alkyl groups typically contain from 1 to 30 carbon atoms. In some embodiments, the alkyl groups contain 1 to 20 carbon atoms, 1 to 10 carbon atoms, 1 to 6 carbon atoms, 1 to 4 carbon atoms, or 1 to 3 carbon atoms. Examples of “alkyl” groups include, but are not limited to, methyl, ethyl, n-propyl, n-butyl, n-pentyl, isobutyl, t-butyl, isopropyl, n-octyl, n-heptyl, ethylhexyl, cyclopentyl, cyclohexyl, cycloheptyl, adamantyl, norbornyl, and the like. As used herein, “Me” refers to a methyl group.

The term “alkylene” refers to a divalent group that is a radical of an alkane and includes groups that are linear, branched, cyclic, bicyclic, or a combination thereof. Unless otherwise indicated, the alkylene group typically has 1 to 30 carbon atoms. In some embodiments, the alkylene group has 1 to 20 carbon atoms, 1 to 10 carbon atoms, 1 to 6 carbon atoms, or 1 to 4 carbon atoms. Examples of “alkylene” groups include methylene, ethylene, 1,3-propylene, 1,2-propylene, 1,4-butylene, 1,4-cyclohexylene, and 1,4-cyclohexyldimethylene.

The term “heteroalkylene” refers to a divalent radical of a heteroalkane, which is an alkane having catenary heteroatoms) having at least one catenary O or NH group. Unless otherwise indicated, the heteroalkylene group typically has 1 to 10 carbon atoms, 2 to 10 carbon atoms, 1 to 6 carbon atoms, 1 to 4 carbon atoms, or 1 to 3 carbon atoms, and up to 6 heteroatoms.

Each of “alkenyl” and “ene” refers to a monovalent linear or branched unsaturated aliphatic group with one or more carbon-carbon double bonds, e.g., vinyl.

The term “aromatic” refers to C3-C40, suitably C3-C30, aromatic groups including both carbocyclic aromatic groups as well as heterocyclic aromatic groups containing one or more of the heteroatoms, O, N, or S, and fused ring systems containing one or more of these aromatic groups fused together.

The term “aryl” refers to a monovalent group that is aromatic and, optionally, carbocyclic. The aryl has at least one aromatic ring. Any additional rings can be unsaturated, partially saturated, saturated, or aromatic. Optionally, the aromatic ring can have one or more additional carbocyclic rings that are fused to the aromatic ring. Unless otherwise indicated, the aryl groups typically contain from 6 to 30 carbon atoms. In some embodiments, the aryl groups contain 6 to 20, 6 to 18, 6 to 16, 6 to 12, or 6 to 10 carbon atoms. Examples of an aryl group include phenyl, naphthyl, biphenyl, phenanthryl, and anthracyl.

The term “arylene” refers to a divalent group that is aromatic and, optionally, carbocyclic. The arylene has at least one aromatic ring. Optionally, the aromatic ring can have one or more additional carbocyclic rings that are fused to the aromatic ring. Any additional rings can be unsaturated, partially saturated, or saturated. Unless otherwise specified, arylene groups often have 6 to 20 carbon atoms, 6 to 18 carbon atoms, 6 to 16 carbon atoms, 6 to 12 carbon atoms, or 6 to 10 carbon atoms.

The term “aralkyl” refers to a monovalent group that is an alkyl group substituted with an aryl group (e.g., as in a benzyl group). The term “alkaryl” refers to a monovalent group that is an aryl substituted with an alkyl group (e.g., as in a tolyl group). Unless otherwise indicated, for both groups, the alkyl portion often has 1 to 10 carbon atoms, 1 to 6 carbon atoms, or 1 to 4 carbon atoms and an aryl portion often has 6 to 20 carbon atoms, 6 to 18 carbon atoms, 6 to 16 carbon atoms, 6 to 12 carbon atoms, or 6 to 10 carbon atoms.

As used herein, the term “primary amino group” refers to the amino group —NH₂. The term “secondary amino group” refers to an amino group of formula —NHR₉ where R₉ is an alkyl. The term “tertiary amino group” refers to an amino group of formula —NR₉R₉ where each R₉ is an alkyl. The term “quaternary amino group” refers to an amino group of formula —N⁺R₉R₉R₉ where each R₉ is an alkyl. Suitable alkyl groups for each R₉ (independently) typically have 1 to 20 carbon atoms, 1 to 10 carbon atoms, 1 to 6 carbon atoms, or 1 to 4 carbon atoms.

As used herein, the term “(meth)acrylate” is a shorthand reference to acrylate, methacrylate, or combinations thereof, “(meth)acrylic” is a shorthand reference to acrylic, methacrylic, or combinations thereof, and “(meth)acryl” is a shorthand reference to acryl and methacryl groups. “Acryl” refers to derivatives of acrylic acid, such as acrylates, methacrylates, acrylamides, and methacrylamides. By “(meth)acryl” is meant a monomer or oligomer having at least one acryl or methacryl groups, and linked by an aliphatic segment if containing two or more groups. As used herein, “(meth)acrylate-functional compounds” are compounds that include, among other things, a (meth)acrylate moiety.

As used herein, the term “light absorbing material” refers to a material that absorbs or scatters wavelengths of light in at least a portion of the visible spectrum or near infrared spectrum, i.e., from 400 nm to 1500 nm.

As used herein, the term “peak wavelength” refers to a single wavelength in which the emission spectrum of a light source achieves its maximum amount.

As used herein, the term “transparent” refers to a material that has at least 50% transmittance, 70% transmittance, or optionally greater than 90% transmittance over at least a 30 nanometer (nm) wavelength band within a particular range of wavelengths and has a thickness of 10 millimeters or less. Suitable ranges of wavelengths include for instance, between 200 nm and 400 nm, between 400 nm and 700 nm, or between 700 nm and 1300 nm.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure.

In this application, terms such as “a”, “an”, and “the” are not intended to refer to only a singular entity, but include the general class of which a specific example may be used for illustration. The terms “a”, “an”, and “the” are used interchangeably with the term “at least one.” The phrases “at least one of” and “comprises at least one of” followed by a list refers to any one of the items in the list and any combination of two or more items in the list.

As used herein, the term “or” is generally employed in its usual sense including “and/or” unless the content clearly dictates otherwise. The term “and/or” means one or all of the listed elements or a combination of any two or more of the listed elements.

Also herein, all numbers are assumed to be modified by the term “about” and preferably by the term “exactly.” As used herein in connection with a measured quantity, the term “about” refers to that variation in the measured quantity as would be expected by the skilled artisan making the measurement and exercising a level of care commensurate with the objective of the measurement and the precision of the measuring equipment used. Also herein, the recitations of numerical ranges by endpoints include all numbers subsumed within that range as well as the endpoints (e.g., 1 to 5 includes 1, 1.5, 2, 2.75, 3, 3.80, 4, 5, etc.).

As used herein as a modifier to a property or attribute, the term “generally”, unless otherwise specifically defined, means that the property or attribute would be readily recognizable by a person of ordinary skill but without requiring absolute precision or a perfect match (e.g., within +/−20% for quantifiable properties). The term “substantially”, unless otherwise specifically defined, means to a high degree of approximation (e.g., within +/−10% for quantifiable properties) but again without requiring absolute precision or a perfect match. Terms such as same, equal, uniform, constant, strictly, and the like, are understood to be within the usual tolerances or measuring error applicable to the particular circumstance rather than requiring absolute precision or a perfect match.

Layer-by-layer (LbL) assembly is a simple bottom-up coating technique wherein a substrate is alternately dipped in solutions of oppositely charged/highly interacting materials. Compared to some other techniques, LbL is scalable and can provide nanoscale control in coating thickness and composition. Furthermore, it can accommodate a diverse array of building blocks and coat numerous substrates. Due to its versatility, LbL enables many applications including the development of degradable coatings for delivery and patterning. Since a wide range of materials can be assembled into LbL coatings, degradation can be triggered through several mechanisms. These may be through pH-induced hydrolysis of esters in the polyelectrolyte backbone, reduction of disulfide-stabilized LbL coatings, electrical switching of polyelectrolyte charges, or enzymatic degradation of polyelectrolyte components. Another simple degradation strategy is using charge-shifting polyelectrolytes that contain removable caging groups, which upon exposure to a stimulus, cleave and expose motifs that neutralize the charge of the original polyelectrolyte. A multilayer coating can be assembled using this polycation with a typical polyanion. Upon exposure to a trigger, the polycation's overall charge is significantly reduced and affinity between layers is lost resulting in coating degradation.

Among various stimuli, chemical-based degradation can be challenging when substrates cannot tolerate a change in pH, a reactive reagent or a change in temperature. In contrast, light is particularly attractive for coating degradation because of its selectivity and the emergence of high-power LEDs, which are enabling high photon flux at a narrow wavelength output. Suitable chromophores can be selectively activated, even through barriers such as glass and transparent polymers without damaging other components present in the coating.

It has been discovered that a variety of photocleavable polymers can be incorporated into coatings to selectively remove some or all of the coating upon exposure to light, optionally even when the coating further contains a light absorbing material.

### Articles

In a first aspect, an article is provided. The article comprises:
a) substrate; and
b) a coating disposed on a major surface of the substrate, the coating comprising one or more polyelectrolytes, a photocleavable polymer, and optionally a light absorbing material, wherein the light absorbing material is present and/or the photocleavable polymer includes a polymer of any of Formula I, Formula II, and/or Formula III:

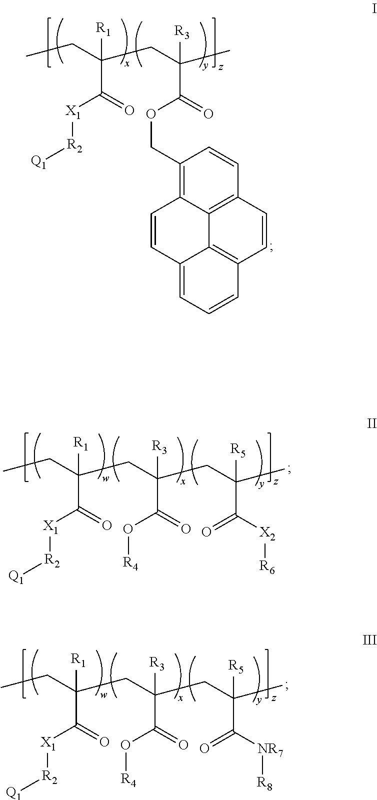

wherein:
R₁ is independently selected from H or methyl;
R₂ is independently selected from an alkylene group or a heteroalkylene group;
Q₁ is independently selected from an amino group selected from a primary amino group, secondary amino group, tertiary amino group, quaternary amino group, or a salt thereof;
R₃ is independently selected from H or methyl;
X₁ is O or NH;
R₄ is independently selected from a photocleavable group selected from the group consisting of arylmethyl, coumarin-4-ylmethyl, nitroaryl, and arylcarbonylmethyl;
R₅ is independently selected from H or methyl; X₁ is O or NH;
X₂ is O or NH;
R₆ is independently selected from OH or a heteroalkylene group;
R₇ is H or methyl;
R₈ is H or methyl;
w is independently a designation of a repeat unit;
x is independently a designation of a repeat unit;
y is independently a designation of a repeat unit; and
z is independently a designation of a repeat unit. Accordingly, the photocleavable polymer is a random copolymer, not a block copolymer. Each of the formulas provided herein having a z unit can be represented without the z with the understanding that the polymer is a random copolymer.

Stated another way, when the photocleavable polymer is not of any of Formula I, Formula II, and/or Formula III, the light absorbing material must be present. When the photocleavable polymer is of any of Formula I, Formula II, and/or Formula III, the light absorbing material can be present but is not required to be present.

It is to be understood that when more than one polymer selected from Formula I, Formula II, and/or Formula III is present, groups sharing the same identifier (e.g., R₃, Q₁, y, etc.) are independently selected from the listed groups, per the use of “independently selected from” in the descriptions of the groups above. For example, in a coating containing the photocleavable polymers of each of Formula I and Formula II, R₃ in Formula I could be H while R₃ in Formula II could be methyl.

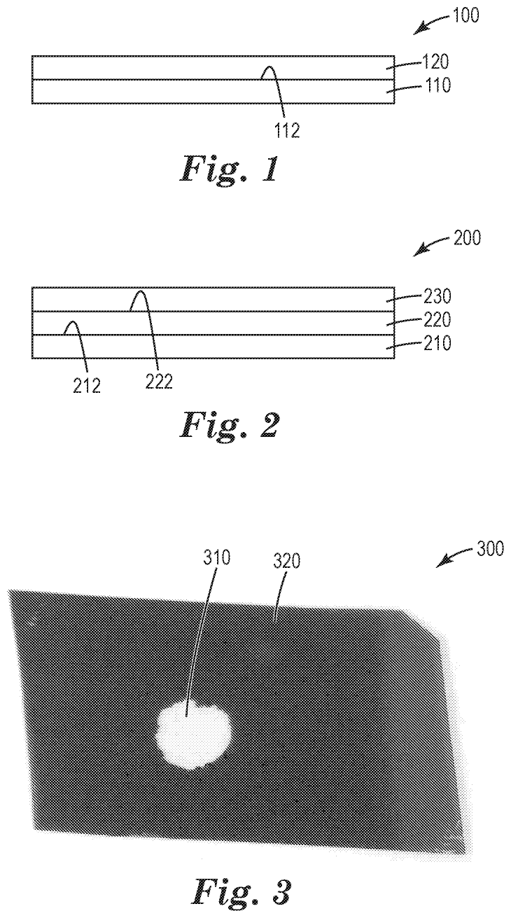

Referring to FIG. 1, an article 100 includes a substrate 110 and a coating 120 disposed on a major surface 112 of the substrate 110. The coating 120 includes one or more polyelectrolytes, a photocleavable polymer, and optionally a light absorbing material.

### Photocleavable Polymers

It is to be understood that a photocleavable polymer is cleavable in at least one of a side chain on the polymer or in the backbone of polymer.

In certain embodiments, a suitable photocleavable polymer is of Formula I:

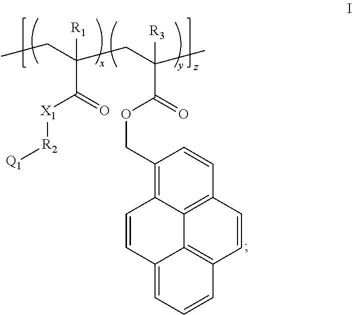

wherein R₁ is H or methyl; R₂ is an alkylene group or a heteroalkylene group; X₁ is O or NH; Q₁ is an amino group selected from a primary amino group, secondary amino group, tertiary amino group, quaternary amino group, or a salt thereof; R₃ is H or methyl; and each of x, y, and z is a designation of a repeat unit. At least 40% of the repeat units of Formula I are of y (which contains a photocleavable group), such as 45% or more, 50%, 55%, or 60% or more. In some cases, x is an integer of 5 to 1000, preferably 20 to 100; and y is an integer of 5 to 1000, preferably 20 to 100. A ratio of x to y may be 1:1 or 1:>1 (i.e., y is greater than x).

In certain embodiments, a suitable photocleavable polymer is of Formula II:

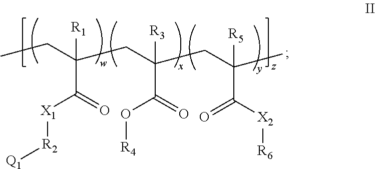

wherein R₁ is H or methyl; R₂ is an alkylene group or a heteroalkylene group; Q₁ is an amino group selected from a primary amino group, secondary amino group, tertiary amino group, quaternary amino group, or a salt thereof; R₃ is H or methyl; X₁ is O or NH; R₄ is a photocleavable group selected from the group consisting of arylmethyl, coumarin-4-ylmethyl, nitroaryl, and arylcarbonylmethyl; R₅ is H or methyl; X₂ is O or NH; R₆ is OH or a heteroalkylene group; and each of w, x, y, and z is a designation of a repeat unit. At least 40% of the repeat units of Formula II are of x (which contains a photocleavable group), such as 45% or more, 50%, 55%, or 60% or more. In some cases, w is an integer of 5 to 1000, preferably 20 to 100; x is an integer of 5 to 1000, preferably 20 to 100; and y is an integer of 1 to 300, preferably 1 to 50. A ratio of w to x to y may be 1:1:<0.3.

In certain embodiments, a suitable photocleavable polymer is of Formula III:

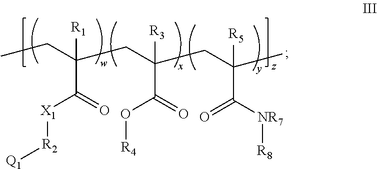

wherein R₁ is H or methyl; R₂ is an alkylene group or a heteroalkylene group; Q₁ is an amino group selected from a primary amino group, secondary amino group, tertiary amino group, quaternary amino group, or a salt thereof; R₃ is H or methyl; X₁ is O or NH; R₄ is a photocleavable group selected from the group consisting of arylmethyl, coumarin-4-ylmethyl, nitroaryl, and arylcarbonylmethyl; R₅ is H or methyl; R₆ is OH or a heteroalkylene group; R₇ is H or methyl; R₈ is H or methyl; and each of w, x, y, and z is a designation of a repeat unit. At least 40% of the repeat units of Formula III are of x (which contains a photocleavable group), such as 45% or more, 50%, 55%, or 60% or more. In some cases, w is an integer of 5 to 1000, preferably 20 to 100; x is an integer of 5 to 1000, preferably 20 to 100; and y is an integer of 1 to 300, preferably 1 to 50. A ratio of w to x to y may be 1:1:<0.3.

In any photocleavable polymer described herein, for any R group that is an alkylene group, the alkylene often has 1 to 10, 1 to 6, 2 to 6, 2 to 4, 3, or 2 carbon atoms. In some embodiments, the alkylene is —CH₂CH₂—, —CH₂CH₂CH₂—, or —C(CH₃)₂—. In any photocleavable polymer described herein, for any R group that is a heteroalkylene group, a suitable heteroalkylene group can have 1 to 5 oxygen heteroatoms and often contains 2 to 10 carbon atoms. In some embodiments, the heteroalkylene is —(CH₂—CH₂—O)ₓ—CH₂CH₂— or —(CH₂—CH₂—CH₂—O)ₓ—CH₂CH₂—CH₂— where x is 1, 2, or 3.

In any photocleavable polymer described herein, Q₁ corresponds to an amino group which includes a primary amino group, secondary amino group, tertiary amino group, quaternary amino group, or a salt thereof. Suitable salts include halides, acetate, sulfates, sulfonates, phosphates, hydroxides, and the like. In select embodiments, the salt comprises chloride or tosylate. In some embodiments, Q₁ comprises a primary amino group. In some embodiments, Q₁ comprises a secondary amino group. In some embodiments, Q₁ comprises a tertiary amino group, such as —N(CH₃)₂. In some embodiments, Q₁ comprises a quaternary amino group.

In certain embodiments, each of R₁, R₃, and R₅ (if present) is methyl.

Each R₄ is independently a photocleavable group selected from the group consisting of arylmethyl, coumarin-4-ylmethyl, nitroaryl, and arylcarbonylmethyl. In some embodiments, the photocleavable group comprises an arylmethyl group, such as one including 6 to 18 carbon atoms (e.g., as polycyclic aromatic hydrocarbon groups having 1 to 4 fused rings). In some embodiments, the photocleavable group comprises coumarin-4-ylmethyl. In some embodiments, the photocleavable group comprises a nitroaryl group, such as one including 5 to 15 carbon atoms. In some embodiments, the photocleavable group comprises an arylcarbonylmethyl group, such as one including 5 to 15 carbon atoms. In select embodiments, a photocleavable group comprises 4 fused rings.

As mentioned above, each of w, x, y, and z is a designation of a repeat unit. When any of w, x, or y is an integer from 5 to 1000, w, x, or y, respectively, is optionally 5 or greater, 10, 15, 20, 25, 30, 35, 40, 45, 50, 60, 70, 80, or 90 or greater; and 1000 or less, 950, 900, 850, 800, 750, 700, 650, 600, 550, 500, 450, 400, 350, 300, 250, 225, 200, 175, 150, 125, or 100 or less. When y is an integer from 1 to 300, y is optionally 1 or greater, 2, 5, 10, 15, 20, 25, 30, 35, or 40 or greater; and 300 or less, 275, 250, 225, 200, 175, 150, 125, 100, 90, 80, 70, 60, or 50 or less.

In select embodiments, the photocleavable polymer comprises poly(dimethylaminoethyl (meth)acrylate-co-7-(diethylamino)-2-oxo-2H-chromen-4-yl)methyl (meth)acrylate). Advantageously, this photocleavable polymer tends to be at least one of a) easier to polymerize, b) less toxic, and c) more efficiently cleaved than other photocleavable polymers. As mentioned above, the term “(meth)acrylate” encompasses both methacrylate and acrylate. In this polymer, they are not mixed between acrylate and methacrylate, but rather include either two acrylates or two methacrylates: poly(dimethylaminoethyl acrylate-co-7-(diethylamino)-2-oxo-2H-chromen-4-yl)methyl acrylate or poly(dimethylaminoethyl methacrylate-co-7-(diethylamino)-2-oxo-2H-chromen-4-yl)methyl methacrylate. A specific photocleavable polymer is that of Formula V:

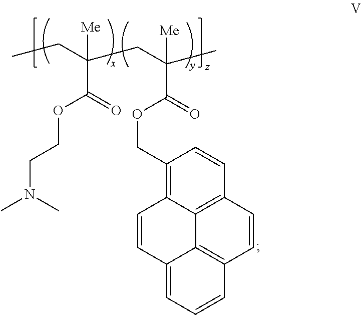

wherein each of x, y, and z is a designation of a repeat unit. In some cases, x is an integer of 5 to 1000, preferably 20 to 100; and y is an integer of 5 to 1000, preferably 20 to 100. A ratio of x to y may be 1:1 or 1:>1 (i.e., y is greater than x). Preferably, y is greater than x.

In some embodiments, a suitable photocleavable polymer is of Formula IV:

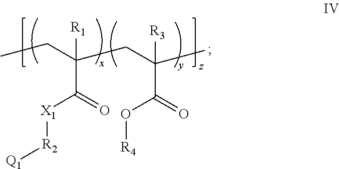

wherein:
R₁ is H or methyl;
R₂ is an alkylene group or a heteroalkylene group;
Q₁ is an amino group selected from a primary amino group, secondary amino group, tertiary amino group, quaternary amino group, or a salt thereof,
R₃ is H or methyl;
X₁ is O or NH;
R₄ is a photocleavable group selected from the group consisting of arylmethyl, coumarin-4-ylmethyl, nitroaryl, and arylcarbonylmethyl;
x is a designation of a repeat unit;
y is a designation of a repeat unit; and
z is a designation of a repeat unit.

In some cases, x is an integer of 5 to 1000, preferably 20 to 100; and y is an integer of 5 to 1000, preferably 20 to 100. A ratio of x to y may be 1:>1 (i.e., when y is larger than x).

In select embodiments, a suitable photocleavable polymer is of Formula VI:

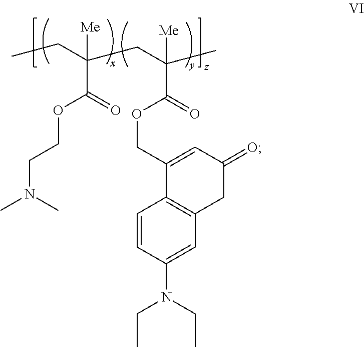

wherein each of x and y is a designation of a repeat unit. Preferably, y is greater than x. In some cases, x is an integer of 5 to 1000, preferably 20 to 100; and y is an integer of 5 to 1000, preferably 20 to 100. A ratio of x to y may be 1:>1 (i.e., when y is larger than x).

In embodiments including the photocleavable polymer of Formula IV or of Formula VI, a light absorbing material is also included in the coating.

### Polyelectrolytes

The coating (e.g., layer) on the substrate comprises one or more polyelectrolytes. The coating is typically deposited by the layer-by-layer (LbL) assembly process. This process is commonly used to assemble films or coatings of oppositely charged polyelectrolytes electrostatically, but other functionalities such as hydrogen bond donor/acceptors, metal ions/ligands, and covalent bonding moieties can be the driving force for film assembly.

“Polyelectrolyte” means a polymer or compound with multiple ionic groups capable of electrostatic interaction, e.g., cationic functional groups and anionic functional groups. “Strong polyelectrolytes” possess permanent charges across a wide range of pH (e.g., polymers containing quaternary ammonium groups or sulfonic acid groups). In certain cases, the polyelectrolytes preferably comprise polymers containing such strong polyelectrolytes.

Besides strong polyelectrolyte coatings, it is also possible to use weak polyelectrolyte coatings, which can be tuned by pH. “Weak polyelectrolytes” possess a pH-dependent level of charge (e.g., polymers containing primary, secondary, or tertiary amines, or carboxylic acids, or phosphonic acids). In certain cases, the polyelectrolytes preferably comprise polymers containing such weak polyelectrolytes. Further, a surface of the coating optionally exhibits a positive zeta potential at a pH in the range of 1-14. Surface zeta potential can be measured by a streaming potential analyzer, also known as an electrokinetic analyzer, available commercially from Anton-Paar USA (Ashland, VA), for example.

Suitable polymers that include a plurality of positively charged ionic (or ionizable) groups (i.e., polycationic polymers) can be derived from these monomers, for example:
Primary amino-containing monomers and their salts (e.g., hydrochloride salts): vinyl amine, allyl amine, aminoalkyl (meth)acrylamide, aminoalkyl (meth)acrylate, 2-N-morpholinoalkyl (meth)acrylate,
Secondary amino-containing monomers and their salts (e.g., hydrochloride salts): alkylaminoalkylene (meth)acrylates such as, for example, 2-(methylamino)ethyl (meth)acylate
Tertiary amino-containing monomers and their salts (e.g., hydrochloride salts): various N,N-dialkylaminoalkyl (meth)acrylates and N,N-dialkylaminoalkyl (meth)acrylamides such as N,N-dimethyl aminoethyl (meth)acrylate, N,N-dimethylaminoethyl (meth)acrylamide, N,N-dimethylaminopropyl (meth)acrylate, N,N-dimethylaminopropyl (meth)acrylamide, N,N-diethylaminoethyl (meth)acrylate, N,N-diethylaminoethyl (meth)acrylamide, N,N-diethylaminopropyl (meth)acrylate, and N,N-diethylaminopropyl (meth)acrylamide, (tert-butylamino)alkyl methacrylate, (tert-butylamino)alkyl methacrylamide
Quaternary amino-containing monomers: methacryloylaminopropyl trimethylammonium chloride, diallyldimethylammonium chloride, 2-acryloxyalkyltrimethylammonium chloride

Typically, the polycationic polymer includes one or more of the photocleavable polymers described in detail above. Exposure of the coating to light leads to the cleavage of the polymer, which introduces an anionic charge on the polycationic polymer. The overall charge of the polymer is thus neutralized, weakening the attractive forces between the layers.

Additionally, some of the more common polycationic polymers used for layer-by-layer coating are: linear and branched poly(ethylenimine) (PEI), poly(allylamine hydrochloride), polyvinylamine, chitosan, polyaniline, polyamidoamine, poly(vinylbenzyltrimethylamine), polydiallyldimethylammonium chloride (PDAC), poly(dimethylaminoethyl methacrylate), poly[(3-methacryloylamino)propyl]-trimethylammonium chloride, and combinations thereof including copolymers thereof.

Suitable polycations may also include polymer latexes, dispersions, or emulsions with positively charged functional groups on the surface. Examples include Sancure 20051 and Sancure 20072 cationic polyurethane dispersions available from Lubrizol Corporation (Wickliffe, OH). Suitable polycations may also include inorganic nanoparticles (for example, aluminum oxide, zirconium oxide, titanium dioxide) suitably below their native isoelectric point, or alternatively surface-modified with positively charged functional groups.

Suitable polymers that include negatively charged ionic (or ionizable) groups (i.e., polyanionic polymers) can be derived from these monomers (and salts thereof), for example: Acid monomers: (meth)acrylic acid, ß-carboxyethyl (meth)acylate, 2-(meth)acryloyloxyethyl phthalic acid, 2-(meth)acryloyloxy succinic acid, vinyl phosphonic acid, vinyl sulfonic acid, styrene sulfonic acid, and 2-acrylamido-2-methylpropane sulfonic acid, (meth)acrylate salts (i.e., zinc acrylate, zirconium acrylate, etc.), carboxyethyl (meth)acrylate salts (i.e., zirconium carboxyethyl acrylate), 2-sulfoalkyl (meth)acrylate, phosphonoalkyl (meth)acrylate, phosphoric acid 2-hydroxyethyl methacrylate ester.

Some of the more common polyanionic polymers used for layer-by-layer coating are: poly(vinyl sulfate), poly(vinyl sulfonate), poly(acrylic acid) (PAA), poly(methacrylic acid), poly(styrene sulfonate), dextran sulfate, heparin, hyaluronic acid, carrageenan, carboxymethylcellulose, alginate, sulfonated tetrafluoroethylene based fluoropolymers such as Nafion®, poly(vinylphosphoric acid), poly(vinylphosphonic acid), and combinations thereof including copolymers thereof.

Suitable polyanions may also include polymer latexes, dispersions, or emulsions with negatively charged functional groups on the surface. Such polymers are available, for example, under the JONCRYL tradename (BASF, Florham Park, NJ), CARBOSET tradename (Lubrizol Corporation), and NEOCRYL tradename (DSM Coating Resins, Wilmington, MA). Suitable anions may also include inorganic nanoparticles (for example, silicon oxide, aluminum oxide, zirconium oxide, titanium dioxide, nano-clay) suitably above their native isoelectric point, or alternatively surface-modified with negatively charged functional groups.

The molecular weight of the polyelectrolyte polymers can vary, typically ranging from about 1,000 g/mole to about 1,000,000 g/mole. In some embodiments, the weight average molecular weight (Mw) of the negatively charged anionic layer ranges from 50,000 g/mole to 150,000 g/mole. In some embodiments, the weight average molecular weight (Mw) of the positively charged cationic layer ranges from 50,000 g/mole to 300,000 g/mole or from 10,000 g/mole to 50,000 g/mole.

Typically, the polyelectrolyte is prepared and applied to the substrate surface as an aqueous solution. The term “aqueous” means that the liquid of the coating contains at least 85 percent by weight of water. It may contain a higher amount of water such as, for example, at least 90, 95, or even at least 99 percent by weight of water or more. The aqueous liquid medium may comprise a mixture of water and one or more water-soluble organic cosolvent(s), in amounts such that the aqueous liquid medium forms a single phase. Examples of water-soluble organic cosolvents include methanol, ethanol, isopropanol, 2-methoxyethanol, 3-methoxypropanol, 1-methoxy-2-propanol, tetrahydrofuran, and ketone or ester solvents. The amount of organic cosolvent typically does not exceed 15 wt. % of the total liquids of the coating composition. The aqueous polyelectrolyte composition for use in layer-by-layer assembly typically comprises at least 0.01 wt. %, 0.05 wt. % or 0.1 wt. % of polyelectrolyte and typically no greater than 5 wt. %, 4 wt. %, 3 wt. %, 2 wt. % or 1 wt. %.

In some embodiments, the aqueous solutions further comprise a “screening agent”, an additive that promotes even and reproducible deposition by increasing ionic strength and reducing interparticle electrostatic repulsion. In the case of aqueous solutions comprising soluble polyelectrolytes, the screening agents can change the conformation of the polymer chains, thereby altering the thickness of the resulting coating as well as the degree of intrinsic versus extrinsic charge compensation. Intrinsic charge compensation occurs when a positively charged functional group on one material (e.g., polymer) is charge neutralized by a negatively charged functional group on another material (e.g., polymer). Extrinsic charge compensation occurs when a charged functional group on a material (e.g., polymer) is charge neutralized by a small counterion (e.g., a positively charged functional group neutralized by a chloride ion, or a negatively charged functional group neutralized by a sodium ion). Suitable screening agents include any low molecular weight salts such as halide salts, sulfate salts, nitrate salts, phosphate salts, fluorophosphate salts, and the like. Examples of halide salts include chloride salts such as LiCl, NaCl, KCl, CaCl₂, MgCl₂, NH₄Cl and the like, bromide salts such as LiBr, NaBr, KBr, CaBr₂, MgBr₂, and the like, iodide salts such as LiI, NaI, KI, CaI₂, MgI₂, and the like, and fluoride salts such as, NaF, KF, and the like. Examples of sulfate salts include Li₂SO₄, Na₂SO₄, K₂SO₄, (NH₄)₂SO₄, MgSO₄, CoSO₄, CuSO₄, ZnSO₄, SrSO₄, Al₂(SO₄)₃, and Fe₂(SO₄)₃. Organic salts such as (CH₃)₃CCl, (C₂H₅)₃CCl, and the like are also suitable screening agents. Suitable screening agent concentrations can vary with the ionic strength of the salt. In some embodiments, the aqueous solution comprises (e.g., NaCl) screening agent at a concentration ranging from 0.01 M to 2 M.

Typically, this LbL deposition process involves exposing the substrate having a surface charge, to a series of liquid solutions, or baths. This can be accomplished by immersion of the substrate into liquid baths (also referred to as dip coating), spraying, spin coating, roll coating, inkjet printing, and the like. Exposure to the first polyion (e.g., polyelectrolyte bath) liquid solution, which has charge opposite that of the substrate, results in charged species near the substrate surface adsorbing quickly, establishing a concentration gradient, and drawing more polyelectrolyte from the bulk solution to the surface. Further adsorption occurs until a sufficient layer has developed to mask the underlying charge and reverse the net charge of the substrate surface. In order for mass transfer and adsorption to occur, this exposure time is typically on the order of seconds to minutes. The substrate is then removed from the first polyion (e.g., bath) liquid solution, and is then exposed to a series of water rinse baths to remove any physically entangled or loosely bound polyelectrolyte. Following these rinse (e.g., bath) liquid solutions, the substrate is then exposed to a second polyion liquid solution, which has charge opposite that of the first polyion (e.g., bath) liquid solution. Once again adsorption occurs, since the surface charge of the substrate is opposite that of the second (e.g., bath) liquid solution. Continued exposure to the second polyion (e.g., bath) liquid solution then results in a reversal of the surface charge of the substrate. A subsequent rinsing can be performed to complete the cycle. This sequence of steps is said to build up one layer pair, also referred to herein as a “bi-layer” of deposition and can be repeated as desired to add further layer pairs to the substrate. In one embodiment, the plurality of layers deposited by layer-by-layer assembly is a polyelectrolyte stack comprising an organic polymeric polyion (e.g., cation) and an organic polymeric counterion (e.g., anion).

In some embodiments, the coating includes a first plurality of bi-layers of polycation/polyanion, in which some or all of the polycation comprises the photocleavable polymer. In some embodiments, the coating includes a second plurality of bi-layers of polycation/polyanion, in which the polyanion of the second plurality of bi-layers comprises a light absorbing material such as a pigment.

Some examples of suitable processes include those described in Krogman et al., U.S. Pat. No. 8,234,998; Hammond-Cunningham et al., US2011/0064936; and Nogueira et al., U.S. Pat. No. 8,313,798. Layer-by layer dip coating can be conducted using a StratoSequence VI (nanoStrata Inc., Tallahassee, FL) dip coating robot.

### Light Absorbing Materials

As mentioned above, the coating optionally includes a light absorbing material. Accordingly, in some embodiments the light absorbing material is present in the coating. The light absorbing material may be a colorant, dye, or pigment. Other light absorbing materials can include particles or other scattering elements that can function to block light from being transmitted. When the light absorbing material is a pigment, a suitable pigment includes carbon black.

The location of a light absorbing material can vary. For instance, the light absorbing material may be in a coating layer (e.g., as a polyanion in a polycation/polyanion LbL coating or infused into a coating) or on a layer. A layer containing the light absorbing material typically has a thickness of 50 nm or greater, 75 nm, 100 nm, 125 nm, 150 nm, 200 nm, 250 nm, or 300 nm or greater; and 3 micrometers or less. When the light absorbing material is on a layer, a separate layer may be present containing the light absorbing material. For instance, referring to FIG. 2, an article 200 includes a substrate 210 and a first coating 220 disposed on a major surface 212 of the substrate 210 and a second coating 230 disposed on a major surface 222 of the first coating 220. The first coating 220 includes one or more polyelectrolytes, a photocleavable polymer, and optionally a light absorbing material, and the second coating 230 includes the light absorbing material. In some cases, the second coating 230 includes the light absorbing material as a polyanion in a polycation/polyanion LbL coating.

Suitable cationic (e.g., basic) dyes include, for example and without limitation, Basic Blue 7, Basic Blue 9 (methylene blue), Basic Blue 26, Basic Violet 2 and Basic Violet 14, Basic Yellow 57, Basic Red 76, Basic Blue 16, Basic Blue 347 (Cationic Blue 347/Dystar), HC Blue No. 16, Basic Blue 99, Basic Brown 16, Basic Brown 17, Basic Yellow 57, Basic Yellow 87, Basic Orange 31, or Basic Red 51.

Suitable anionic (e.g., acid) dyes include, for example and without limitation, one or more compounds from the following group: Acid Yellow 1 (D&C Yellow 7, Citronine A, Ext. D&C Yellow No. 7, Japan Yellow 403, CI 10316, COLIPA No. B001), Acid Yellow 3 (COLIPA No.: C 54, D&C Yellow No. 10, Quinoline Yellow, E104, Food Yellow 13), Acid Yellow 9 (CI 13015), Acid Yellow 17 (CI 18965), Acid Yellow 23 (COLIPA n ° C. 29, Sicovit Tartrazine 85 E 102 (BASF), Tartrazine, Food Yellow 4, Japan Yellow 4, FD&C Yellow No. 5), Acid Yellow 36 (CI 13065), Acid Yellow 121 (CI 18690), Acid Orange 6 (CI 14270), Acid Orange 7 (2-Naphthol orange, Orange II, CI15510, D&C Orange 4, COLIPA No. C015), Acid Orange 10 (CI16230; Orange G sodium salt), Acid Orange 11 (CI 45370), Acid Orange 15 (CI 50120), Acid Orange 20 (Cl 14600), Acid Orange 24 (BROWN 1; Cl 20170; KATSU201); ACID ORANGE 24; Japan Brown 201; D& C Brown No. 1), Acid Red 14 (C.l.14720), Acid Red 18 (E124, Red 18; Cl 16255), Acid Red 27 (E 123, Cl 16185, C-Red 46, Echtrot D, FD&C Red No. 2, Food Red 9, Naphthol Red S), Acid Red 33 (Red 33, Fuchsia Red, D&C Red 33, Cl 17200), Acid Red 35 (CI 18065), Acid Red 51 (CI 45430, Pyrosine B, tetraiodofluorescein, Eosin J, iodosine), Acid Red 52 (CI 45100, Food Red 106, Solar Rhodamine B, Acid Rhodamine B, Red No. 106 Pontacyl Brilliant pink), Acid Red 73 (CI27290), Acid Red 87 (Eosin, CI45380), Acid Red 92 (COLIPA no. C53, CI45410), Acid Red 95 (CI 45425, Erythtosine, Simacid erythrosine Y), Acid Red 184 (CI 15685), Acid Red 195, Natural Red 4 (carminic acid), Acid Violet 43 (Jarocol Violet 43, Ext. D&C Violet no. 2, CI60730, COLIPA No. C063), Acid Violet 49 (CI 42640), Acid Violet 50 (CI50325), Acid Blue 1 (patent Blue, CI 42045), Acid Blue 3 (patent Blue V, CI42051), Acid Blue 7 (CI 42080), Acid Blue 104 (CI 42735), Acid Blue 9 (E 133, patent Blue AE, amido Blue AE, Erioglaucin A, CI 42090, CI Food Blue 2), Acid Blue 62 (CI 62045), Acid Blue 74 (E 132, CI 73015), Acid Blue 80 (CI 61585), Trypan blue, Acid Green 3 (CI 42085, Foodgreen1), Acid Green 5 (CI 42095), Acid Green 9 (CI 42100), Acid Green 22 (CI 42170), Acid Green 25 (CI 61570, Japan Green 201, D&C Green No. 5), Acid Green 50 (Brilliant Acid Green BS, CI 44090, Acid Brilliant Green BS, E 142), Acid Black 1 (Black No. 401, Naphthene Black 10B, Amido Black 10B, CI 20470, COLIPA No. B15), Acid Black 52 (CI 15711), Eriochrome Black T, Nigrosin (water soluble), Food Yellow 8 (CI 14270), Food Blue 5, D&C Yellow 8, D&C Green 5, D&C Orange 10, D&C Orange 11, D&C Red 21, D&C Red 27, D&C Red 33, D&C Violet 2, and/or D&C Brown 1.

Some of major classes of dyes/pigments include phthalocyanines, cyanine, transition metal dithioline, squarylium, croconium, quinones, anthraquinones, iminium, pyrylium, thiapyrylium, azulenium, azo, perylene and indoanilines. Many of these dyes and pigments can exhibit both visible and/or infrared lights absorption as well. Further, many different types of visible dyes and colorants may be used such as acid dyes, azoic coloring matters, coupling components, diazo components. Basic dyes include developers, direct dyes, disperse dyes, fluorescent brighteners, food dyes, ingrain dyes, leather dyes, mordant dyes, natural dyes and pigments, oxidation bases, pigments, reactive dyes, reducing agents, solvent dyes, sulfur dyes, condense sulfur dyes, vat dyes Some of the organic pigments may belong to one or more of monoazo, azo condensation, insoluble metal salts of acid dyes and disazo, naphthols, arylides, diarylides, pyrazolone, acetoarylides, naphthanilides, phthalocyanines, anthraquinone, perylene, flavanthrone, triphendioxazine, metal complexes, quinacridone, polypyrrolopyrrole, etc.

Suitable pigments are available commercially as colloidally stable water dispersions from manufacturers such as Cabot, Clariant, Orient, Penn Color, Sun Color, DuPont, Dai Nippon and DeGussa. Particularly suitable pigments include those available from Cabot Corporation under the CAB-O-JET® name, for example 200 (black), 300 (black), 352K (black), 400 (black), 250C (cyan), 260M (magenta), and 270Y (yellow). Multiple pigments may be utilized to achieve a specific hue or shade or color in the final product. When multiple pigments are used, the materials are selected to ensure their compatibility and performance both with each other and with the optical product components. The light absorbing (e.g., pigment) particles are typically surface treated to impart ionizable functionality. Examples of suitable ionizable functionality for light absorbing (e.g., pigment) particles include sulfonate functionality, carboxylate functionality as well as phosphate or bisphosphonate functionality. In some embodiments, surface treated light absorbing (e.g., pigment) particles having ionizable functionality arm commercially available, such as those listed above. When the light absorbing (e.g., pigment) particles are not pre-treated, the light absorbing (e.g., pigment) particles can be surface treated to impart ionizable functionality as known in the art. A pigment can be coated onto an LbL coating, for instance by immersion (e.g., dip coating) of the coated microstructured film into an aqueous suspension containing the pigment, or by spraying, spin coating, roll coating, inkjet printing, and the like. Preferably, the pigment should have a sufficiently positive or negative zeta potential such that it will adsorb onto the surface of an LbL coating with zeta potential having the opposite sign in the pigment suspension.

### Substrates

Articles according to the present disclosure each include a substrate. Exemplary substrates may be at least one of a polymer, a glass, a paper, a metal, or a ceramic. The substrate may be rigid or flexible. In some cases, the substrate is sufficiently flexible for use in roll-to-roll processing in making exemplary articles.

A polymer substrate may comprise any of a variety of materials including polyesters such as polyethylene terephthalate, polyethylene naphthalate, copolyesters or polyester blends based on naphthalene dicarboxylic acids; polycarbonates; polystyrenes; styrene-acrylonitriles; cellulose acetates; polyether sulfones; poly(meth)acrylates such as polymethylmethacrylate; polyurethanes; polyvinyl chloride; polycyclo-olefins; polyimides; or combinations or blends thereof. Particular examples include polyethylene terephthalate, polymethyl methacrylate, polyvinyl chloride, and cellulose triacetate. Preferable examples include polyethylene terephthalate, polyethylene naphthalate, cellulose triacetate, polypropylene, polyester, polycarbonate, polymethylmethacrylate, polyimide, polyamide, or a blend thereof.

In select embodiments, the substrate is transparent (e.g., at least 50% transmittance of wavelengths in a desired range). Being transparent can be useful when the photocleavable polymer is to be irradiated with light through the substrate instead of directly on the coating.

Advantageously, the use of a photocleavable polymer in coatings according to the present disclosure enables forming a pattern of the coating on a substrate by selectively photocleaving portions of the coating. Hence, in some embodiments of exemplary articles, the coating is present on the substrate in a pattern. For instance, referring to FIG. 3, a photograph of an article 300 is provided, in which a coating 320 comprising a carbon black pigment is disposed on a substrate 310. The coating 320 has a pattern such that the coating 320 covers the substrate 310 except for in an area having a shape that is substantially circular, through which the substrate 310 is visible.

The article 300 is from Example 5.

### Methods

In a second aspect, the present disclosure provides a method of making an article. The article may be any article according to the first aspect described in detail above. The method comprises:
applying a coating to a major surface of a substrate, the coating comprising one or more polyelectrolytes, a photocleavable polymer, and optionally a light absorbing material, wherein the light absorbing material is present and/or the photocleavable polymer includes a polymer of any of Formula I, Formula II, and/or Formula III:

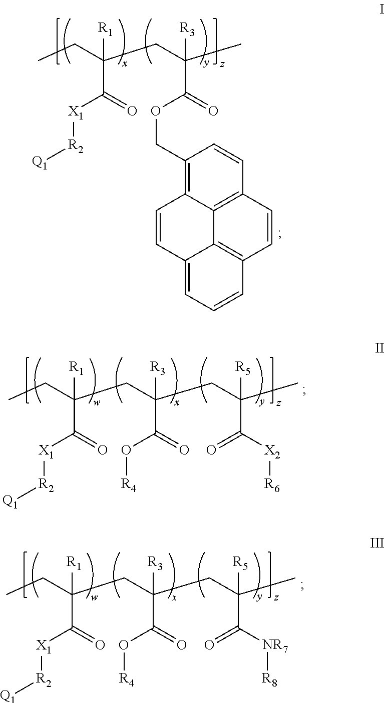

wherein R₁ is independently selected from H or methyl; R₂ is independently selected from an alkylene group or a heteroalkylene group; Q₁ is independently selected from an amino group selected from a primary amino group, secondary amino group, tertiary amino group, quaternary amino group, or a salt thereof, R₃ is independently selected from H or methyl; X₁ is O or NH; R₄ is independently selected from a photocleavable group selected from the group consisting of arylmethyl, coumarin-4-ylmethyl, nitroaryl, and arylcarbonylmethyl; R₅ is independently selected from H or methyl; X₂ is O or NH; R₆ is independently selected from OH or a heteroalkylene group; R₇ is H or methyl; R₈ is H or methyl; and each of w, x, y, and z is a designation of a repeat unit.

Each of R₁, R₂, R₃, R₄, R₅, R₆, R₇, R₈, Q₁, X₁, X₂, w, x, y, and z is as described in detail above with respect to the first aspect.

Often, the coating is applied by applying a first layer having a first bonding group to the substrate and applying a second layer having a second bonding group to the first layer, wherein the second bonding group is complementary to the first bonding group, such as oppositely charged groups (e.g., H-donor and acceptor groups, etc.) The coating is typically deposited by the layer-by-layer (LbL) assembly process, as described in detail above with respect to the first aspect.

Coatings having a pattern on the substrate may be formed according to methods of the present disclosure. As such, additional optional steps may include irradiating the article with spatioselective light; and rinsing the irradiated article to remove the irradiated portions of the coating, thereby providing an article in which the coating is present on the substrate in a pattern. Suitable spatioselective light may include an array of collimated or focused light such that the light is irradiated at one or more select locations of the coating to cause photocleaving of photocleavable polymer(s) at substantially only the desired area(s). Spatioselective irradiation can be performed by collimated light instruments, such as those commercially available from Neutronix Quintel (Morgan Hill, CA), e.g., the U-line 7000 Mask Aligner and the NXQ8012 Series Mask Aligner.

In certain embodiments, additional optional steps to form a pattern include using a photomask. Such steps include covering portions of the coating with a photomask; irradiating the masked article with light; and rinsing the irradiated article to remove the uncovered portions of the coating to provide an article in which the coating is present on the substrate in a pattern. It will be understood that the term “rinsing” includes contacting the coating with a solvent (e.g., water and/or an organic solvent) or a washing solution (e.g., a salt solution). Rinsing may be referred to as “developing” (e.g., developing the pattern). Often, the method further comprises drying the article after the rinsing.

Suitable photomasks include both physical and digital photomasks. A physical photomask is an object (that is usually planar) that includes one or more portions that are transparent to irradiation wavelengths desired to be transmitted through the substrate and one or more portions that blocks the irradiation wavelengths from passing through the photomask. A digital photomask employs computer controls to select specific locations from which light will be irradiated and other locations from which no light will be irradiated. Typically, when the photomask is physical (instead of digital), such a method further comprises removing the photomask from the article after irradiating the article with light.

The irradiating light has a peak wavelength of greater than 200 nanometers and less than 400 nanometers, greater than 400 nanometers and less than 700 nanometers, or greater than 700 nanometers and less than 1300 nanometers. The light source is not particularly limited. In certain embodiments, light emitting diodes (LEDs) may be employed, such as a 365 nm and 395 nm UV-LED commercially available under the trade designation “OMNICURE AC4 Series” including AC450, AC450P, AC475, and AC475P from Excelitas Technologies Corp. (Waltham, MA); or a 450 nm LED commercially available under the trade designation “3M Blue Light Gun” from 3M Company (Saint Paul, MN).

Optionally, the article is irradiated with light for 30 seconds or greater, 45 seconds, 60 seconds, 75 seconds, 90 seconds, or 100 seconds or greater; and 3 minutes or less, 2.5 minutes, 2 minutes, or 1.5 minutes or less.

Depending on the optical characteristics of the article, the article may be irradiated through the substrate and into the coating, irradiating the coating directly, or both. For instance, in embodiments where one layer of the coating contains a light absorbing material that would undesirably block light from reaching the photocleavable polymer present in another layer the coating, the irradiating includes directing the light such that the light contacts the layer containing the photocleavable polymer prior to contacting the layer containing the light absorbing material. In such cases, this involves directing the light through the substrate and the substrate is transparent to at least some of the wavelengths that cleave the photocleavable polymer. It has been unexpectedly discovered that more than one layer of a coating can selectively be removed from the substrate even when just the layer in contact with the substrate contains a photocleavable polymer, upon exposure to light irradiation. In embodiments where no light absorbing material is present or would not undesirably block light from reaching the photocleavable polymer, the light may be directed at either the coating or the substrate. As such, in some embodiments, the irradiating comprises directing the light at the coating.

### Exemplary Embodiments

In a first embodiment, the present disclosure provides an article. The article comprises a substrate and a coating disposed on a major surface of the substrate. The coating comprises one or more polyelectrolytes, a photocleavable polymer, and optionally a light absorbing material. The light absorbing material is present and/or the photocleavable polymer includes a polymer of any of Formula I, Formula II, and/or Formula III:

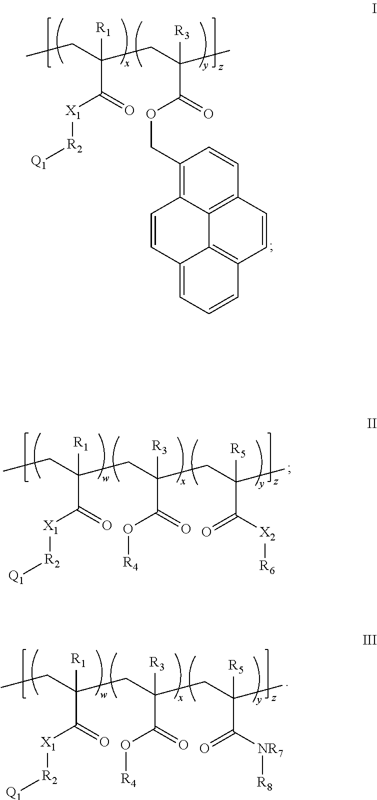

R₁ is independently selected from H or methyl; R₂ is independently selected from an alkylene group or a heteroalkylene group; Q₁ is independently selected from an amino group selected from a primary amino group, secondary amino group, tertiary amino group, quaternary amino group, or a salt thereof, R₃ is independently selected from H or methyl; X₁ is O or NH; R₄ is independently selected from a photocleavable group selected from the group consisting of arylmethyl, coumarin-4-ylmethyl, nitroaryl, and arylcarbonylmethyl; R₅ is independently selected from H or methyl; X₂ is O or NH; R₆ is independently selected from OH or a heteroalkylene group; R₇ is H or methyl; R₈ is H or methyl; and each of w, x, y, and z is a designation of a repeat unit.

In a second embodiment, the present disclosure provides an article according to the first embodiment, wherein the light absorbing material is present.

In a third embodiment, the present disclosure provides an article according to the first embodiment or the second embodiment, wherein the light absorbing material is present and comprises a pigment.

In a fourth embodiment, the present disclosure provides an article according to the second embodiment or the third embodiment, wherein the pigment comprises carbon black.

In a fifth embodiment, the present disclosure provides an article according to any of the first through fourth embodiments, wherein the coating comprises a first plurality of bi-layers of polycation/polyanion, wherein some or all of the polycation comprises the photocleavable polymer.

In a sixth embodiment, the present disclosure provides an article according to the fifth embodiment, wherein the light absorbing material is present in or on the first plurality of bi-layers.

In a seventh embodiment, the present disclosure provides an article according to the sixth embodiment, wherein the light absorbing material is present in a layer disposed on the first plurality of bi-layers.

In an eighth embodiment, the present disclosure provides an article according to the seventh embodiment, wherein the layer containing the light absorbing material has a thickness of 50 nanometers or greater.

In a ninth embodiment, the present disclosure provides an article according to any of the fifth through eighth embodiments, wherein the coating further comprises a second plurality of bi-layers of polycation/polyanion, wherein the polyanion of the second plurality of bi-layers comprises the light absorbing material.

In a tenth embodiment, the present disclosure provides an article according to any of the first through ninth embodiments, wherein the light absorbing material is present and the photocleavable polymer includes a polymer of Formula IV:

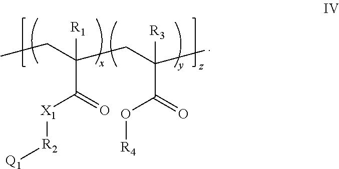

R₁ is H or methyl; R₂ is an alkylene group or a heteroalkylene group; Q₁ is an amino group selected from a primary amino group, secondary amino group, tertiary amino group, quaternary amino group, or a salt thereof, R₃ is H or methyl; X₁ is O or NH; R₄ is a photocleavable group selected from the group consisting of arylmethyl, coumarin-4-ylmethyl, nitroaryl, and arylcarbonylmethyl; and each of x, y, and z is a designation of a repeat unit.

In an eleventh embodiment, the present disclosure provides an article according to any of the first through tenth embodiments, wherein the photocleavable polymer includes a polymer of Formula I:

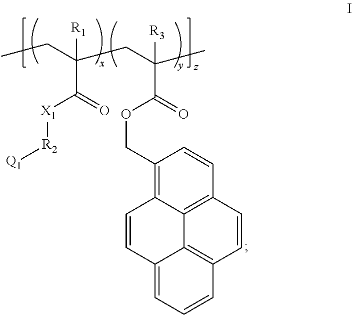

R₁ is H or methyl; R₂ is an alkylene group or a heteroalkylene group; Q₁ is an amino group selected from a primary amino group, secondary amino group, tertiary amino group, quaternary amino group, or a salt thereof, R₃ is H or methyl; X₁ is O or NH; and each of x, y, and z is a designation of a repeat unit.

In a twelfth embodiment, the present disclosure provides an article according to any of the first through eleventh embodiments, wherein the photocleavable polymer includes a polymer of Formula II:

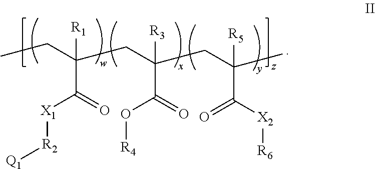

R₁ is H or methyl; R₂ is an alkylene group or a heteroalkylene group; Q₁ is an amino group selected from a primary amino group, secondary amino group, tertiary amino group, quaternary amino group, or a salt thereof, R₃ is H or methyl; X₁ is O or NH; R₄ is a photocleavable group selected from the group consisting of arylmethyl, coumarin-4-ylmethyl, nitroaryl, and arylcarbonylmethyl; R₅ is H or methyl; X₂ is O or NH; R₆ is OH or a heteroalkylene group; and each of w, x, y, and z is a designation of a repeat unit.

In a thirteenth embodiment, the present disclosure provides an article according to any of the first through twelfth embodiments, wherein the photocleavable polymer includes a polymer of Formula III:

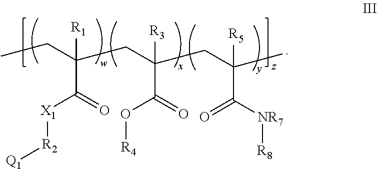

R₁ is H or methyl; R₂ is an alkylene group or a heteroalkylene group; Q₁ is an amino group selected from a primary amino group, secondary amino group, tertiary amino group, quaternary amino group, or a salt thereof, R₃ is H or methyl; X₁ is O or NH; R₄ is a photocleavable group selected from the group consisting of arylmethyl, coumarin-4-ylmethyl, nitroaryl, and arylcarbonylmethyl; R₅ is H or methyl; R₆ is OH or a heteroalkylene group; R₇ is H or methyl; R₈ is H or methyl; and each of w, x, y, and z is a designation of a repeat unit.

In a fourteenth embodiment, the present disclosure provides an article according to any of the first through thirteenth embodiments, wherein the photocleavable polymer includes a polymer of Formula V:

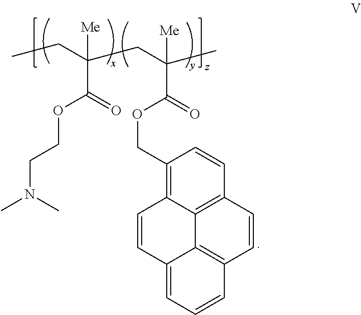

Each of x, y, and z is a designation of a repeat unit.

In a fifteenth embodiment, the present disclosure provides an article according to the fourteenth embodiment, wherein y is greater than x.

In a sixteenth embodiment, the present disclosure provides an article according to any of the first through fifteenth embodiments, wherein the substrate is transparent.

In a seventeenth embodiment, the present disclosure provides an article according to any of the first through sixteenth embodiments, wherein the coating is present on the substrate in a pattern.

In an eighteenth embodiment, the present disclosure provides a method of making an article. The method comprises applying a coating to a major surface of a substrate. The coating comprises a photocleavable polymer, and optionally a light absorbing material, wherein the light absorbing material is present and/or the photocleavable polymer includes a polymer of any of Formula I, Formula II, and/or Formula III:

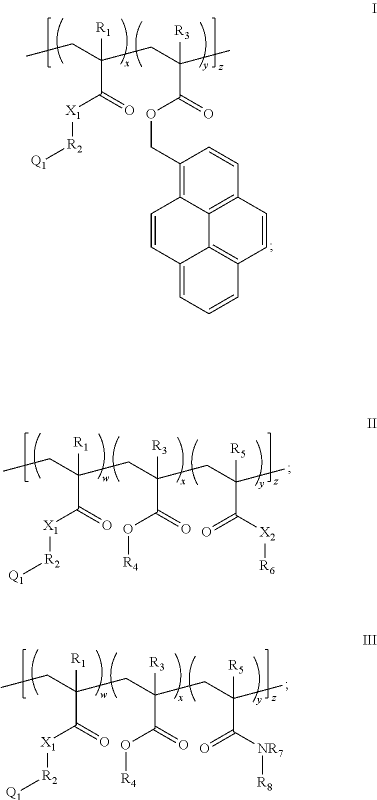

wherein R₁ is independently selected from H or methyl; R₂ is independently selected from an alkylene group or a heteroalkylene group; Q₁ is independently selected from an amino group selected from a primary amino group, secondary amino group, tertiary amino group, quaternary amino group, or a salt thereof, R₃ is independently selected from H or methyl; X₁ is O or NH; R₄ is independently selected from a photocleavable group selected from the group consisting of arylmethyl, coumarin-4-ylmethyl, nitroaryl, and arylcarbonylmethyl; R₅ is independently selected from H or methyl; X₂ is O or NH; R₆ is independently selected from OH or a heteroalkylene group; R₇ is H or methyl; R₈ is H or methyl; and each of w, x, y, and z is a designation of a repeat unit.

In a nineteenth embodiment, the present disclosure provides a method according to the eighteenth embodiment, wherein the coating is applied by applying a first layer having a first bonding group to the substrate and applying a second layer having a second bonding group to the first layer, wherein the second bonding group is complementary to the first bonding group.

In a twentieth embodiment, the present disclosure provides a method according to the eighteenth embodiment or the nineteenth embodiment, wherein the coating is applied by layer-by-layer assembly.

In a twenty-first embodiment, the present disclosure provides a method according to any of the eighteenth through twentieth embodiments, further comprising covering portions of the coating with a photomask; irradiating the masked article with light; and rinsing the irradiated article to remove the uncovered portions of the coating, thereby providing an article in which the coating is present on the substrate in a pattern.

In a twenty-second embodiment, the present disclosure provides a method according to the twenty-first embodiment, further comprising removing the photomask from the article after irradiating the article with light.

In a twenty-third embodiment, the present disclosure provides a method according to any of the eighteenth through twentieth embodiments, further comprising irradiating the article with spatioselective light; and rinsing the irradiated article to remove the irradiated portions of the coating, thereby providing an article in which the coating is present on the substrate in a pattern.

In a twenty-fourth embodiment, the present disclosure provides a method according to the twenty-third embodiment, wherein the spatioselective light comprises array of collimated or focused light.

In a twenty-fifth embodiment, the present disclosure provides a method according to any of the twenty-first through twenty-fourth embodiments, wherein the irradiating light has a peak wavelength of greater than 200 nanometers and less than 400 nanometers.

In a twenty-sixth embodiment, the present disclosure provides a method according to any of the twenty-first through twenty-fourth embodiments, wherein the irradiating light has a peak wavelength of greater than 400 nanometers and less than 700 nanometers.

In a twenty-seventh embodiment, the present disclosure provides a method according to any of the twenty-first through twenty-fourth embodiments, wherein the irradiating light has a peak wavelength of greater than 700 nanometers and less than 1300 nanometers.

In a twenty-eighth embodiment, the present disclosure provides a method according to any of the twenty-first through twenty-seventh embodiments, wherein the irradiating comprises directing the light through the substrate.

In a twenty-ninth embodiment, the present disclosure provides a method according to any of the twenty-first through twenty-seventh embodiments, wherein the irradiating comprises directing the light at the coating.

In a thirtieth embodiment, the present disclosure provides a method according to any of the twenty-first through twenty-ninth embodiments, further comprising drying the article after the rinsing.

In a thirty-first embodiment, the present disclosure provides a method according to any of the twenty-first through thirtieth embodiments, wherein the article is according to any of the first through seventeenth embodiments.

Advantages and embodiments of this invention are further illustrated by the following examples, but the particular materials and amounts thereof recited in these examples, as well as other conditions and details, should not be construed to unduly limit this invention. All parts and percentages are by weight unless otherwise indicated.

### Examples

Unless otherwise noted or apparent from the context, all parts, percentages, ratios, etc. in the Examples and the rest of the specification are by weight. Table 1 (below) lists materials used in the examples and their sources.

TABLE 1
Materials List

| ABBREVIATION | MATERIAL | SOURCE |
|---|---|---|
| DMAEMA | N,N-Dimethylaminoethyl methacrylate | Alfa Aesar, |
| | | Tewksbury, MA, |
| | | USA |
| AIBN | Azobis(isobutyronitrile) | MilliporeSigma, |
| | | Burlington, MA, |
| | | USA |
| DMF | Dimethylformamide (anhydrous) | Acros Organics, |
| | | Fair Lawn, NJ, |
| | | USA |
| DMF-DMA | N,N-Dimethylformamide dimethyl acetal | MilliporeSigma |
| NaIO₄ | Sodium periodate | MilliporeSigma |
| NaBH₄ | Sodium borohydride | MilliporeSigma |
| Inhibitor removers | Inhibitor Removers, replacement packing for | MilliporeSigma |
| | removing hydroquinone and monomethyl ether | |
| | hydroquinone (Product No.: 311332) | |
| PSS | Poly(sodium 4-styrene sulfonate) solution (30 | MilliporeSigma |
| | wt. % in water, average M_{W} ~70,000) | |
| COJ200 | Surface-modified carbon black dispersion | Cabot Corp., |
| | supplied at 20.13% solids in water obtained as | Boston, MA, USA |
| | CAB-O-JET 200 | |
| SC72 | Cationic polyurethane dispersion supplied at | Lubrizol |
| | 27% solids in water obtained as SANCURE | Corp., Wickliffe, |
| | 20072 | OH, USA |
| p-toluenesulfonic | p-toluenesulfonic acid monohydrate | MilliporeSigma |
| acid monohydrate | | |
| PL-92 | A nonionic difunctional block copolymer | BASF |
| | surfactant terminating in primary hydroxyl | Corporation, |
| | groups obtained as PLURONIC L92 | Ludwigshafen, |
| | | Germany |
| NaCl | Sodium Chloride Solution (25 wt. % in water) | Univar Solutions, |
| | | Downers Grove, |
| | | IL, USA |
| HCl | Hydrochloric acid 1N, BAKER ANALYZED | Avantor |
| | volumetric solution, J.T. Baker | Performance |
| | | Materials, LLC, |
| | | Radnor, PA, USA |
| 1-Pyrenemethyl | 1-Pyrenemethyl methacrylate | MilliporeSigma |
| methacrylate | | |
| Methacryloyl | Methacryloyl chloride | MilliporeSigma/ |
| chloride | | Sigma-Aldrich, St. |
| | | Louis, MO |
| THF | Tetrahydrofuran (anhydrous) | MilliporeSigma |
| Coumarin 1 | 7-Diethylamino-4-methylcoumarin | MilliporeSigma |
| COJ250C | Cyan pigment dispersion obtained as CAB-O- | Cabot Corp. |
| | JET 250C | |
| Glass | FISHERBRAND Plain Microscope Slides, | Fisher Scientific, |
| | Precleaned | Hampton, NH |
| PET | Poly(ethylene terephthalate) film with 2.4 mil | 3M Company, St. |
| | thickness (Sample no.: 41-4400-0783-3, Load | Paul, MN |
| | ID G1155492, Lot: G120036F23) | |
| Photomer 6010 | Aliphatic urethane diacrylate | BASF |
| | Obtained as PHOTOMER 6010 | Corporation, |
| | | Florham Park, NJ |
| | | USA |
| SR602 | Ethoxylated (10) bisphenol A diacrylate | Sartomer, Exton, |
| | obtained as SR602 | PA, USA |
| SR601 | Ethoxylated (4) bisphenol A diacrylate | Sartomer |
| | Obtained as SR601 | |
| TMPTA | Trimethylolpropane triacrylate | Cytec Industries, |
| | | Woodland Park, |
| | | NJ, USA |
| PEA (Etermer | Phenoxyethyl acrylate obtained as ETERMER | Eternal Chemical |
| 2010) | 2010 | Co., Ltd., |
| | | Kaohsiung, |
| | | Taiwan |
| Darocur 1173 | 2-Hydroxy-2-methylpropiophenone | BASF |
| | photoinitiator obtained as DAROCUR 1173 | Corporation |
| TPO | Diphenyl(2,4,6-trimethylbenzoyl)phosphine | IGM Resins USA, |
| | oxide photoinitiator obtained as OMNIRAD | Charlotte, NC, |
| | TPO | USA |
| I1035 | Anti-oxidant obtained as IRGANOX 1035 | BASF |
| | | Corporation |

### PREPARATIVE EXAMPLES

### Preparative Example 1

### Preparation of Resin A-coated PET Film Substrate (PE-1)

Resin A was prepared by mixing the materials in Table 2 below with a high-speed mixer (Model: SpeedMixer™ DAC 150 By HAUSCHILD, Germany).

TABLE 2
Materials list for Resin A coating formulation.

| MATERIAL | PARTS BY WEIGHT |
|---|---|
| Photomer 6010 | 60.00 |
| SR602 | 20.00 |
| SR601 | 4.00 |
| TMPTA | 8.00 |
| PEA (Etermer 2010) | 8.00 |
| Darocur 1173 | 0.35 |
| TPO | 0.10 |
| I1035 | 0.20 |

Resin A (about 2 milliliters (mL)) was dispensed with a pipet onto a 6″ wide by 10″ long (15 centimeters (cm) by 25 cm) sheet of PET film (3M, St. Paul, MN), having a thickness of 2.93 mils (74.4 micrometers). The side of the PET film that contacts the resin was primed with a thermoset acrylic polymer (Rhoplex 3208 available from Dow Chemical, Midland, MI). A second sheet of PET film was placed on top, with the unprimed side oriented down, toward the resin. This construction was laminated, spreading out Resin A between the two sheets of PET, using a Catena 65 roll laminator (available from GBC, Lake Zurich, IL) at a temperature of 150° F. (66° C.), speed of 5 feet per minute (ft/min) (1.5 meters per minute (m/min)), and a 1 mm gap. Resin A was cured by sending the laminate through a Heraeus (Hanau, Germany) belt conveyer UV processor (Model #DRS(6)) with an ‘H’ bulb at 500 Watt power. Specifically, the samples were sent through the UV curing station three times at a conveyer speed of 50 ft/min (15 m/min). Next, the top PET film was stripped off by hand.

### Preparative Example 2

### Preparation of Poly(Dimethylaminoethyl Methacrylate-co-Pyrenemethyl Methacrylate) (PE-2)

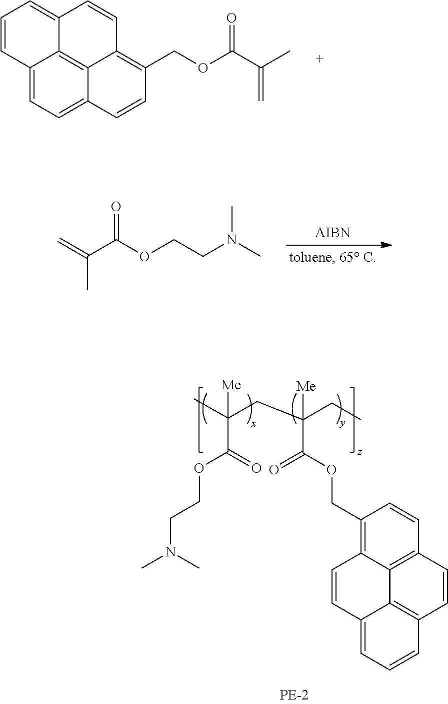

### Synthesis route for poly(dimethylaminoethylmethacrylate-co-pyrenemethyl methacrylate) (PE-2)

Prior to use, N,N-dimethylaminoethyl methacrylate (DMAEMA) was added into a vial with inhibitor removers (MilliporeSigma), allowed to sit for 1 min and then syringed out. Then, a vial fitted with a septum was loaded with azobis(isobutyronitrile) (AIBN, 6 milligrams (mg), 0.0365 millimoles (mmol)), 1-pyrenemethyl methacrylate (321 mg, 1.07 mmol), DMAEMA (0.18 milliliters (mL), 1.07 mmol) and anhydrous toluene (8 mL). The reaction mixture was sparged with argon for 30 minutes (min) and then stirred at 65° C. overnight. After 16 hours (h), the reaction mixture was cooled, concentrated, and precipitated from CHCl₃ into hexanes three times to give the polymer as a white powder.

### Preparative Example 3

### Preparation of Poly(Dimethylaminoethyl Methacrylate-co-7-(diethylamino)-2-oxo-2H-chromen-4-yl)methyl methacrylate) (PE-3C)

PE-3C was synthesized in three steps, as described below.

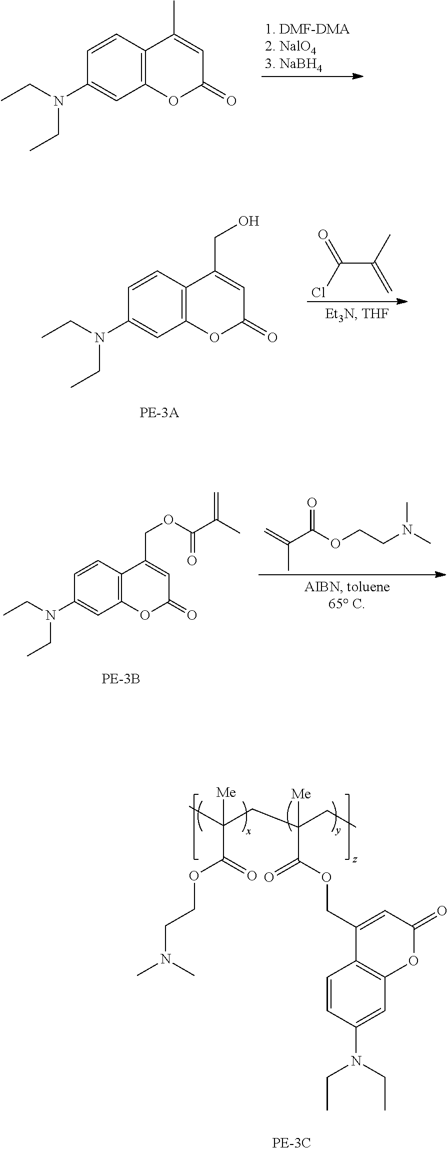

### Synthesis of Poly(dimethylaminoethyl Methacrylate-co-7-(diethylamino)-2-oxo-2H-chromen-4-yl)methyl methacrylate) (PE-3C)

### Step 1: Synthesis of 7-(diethylamino)-4-(hydroxymethyl)-2H-chromen-2-one (PE-3A)

This product was synthesized from 7-diethylamino-4-methylcoumarin (Coumarin 1) according to the fast procedure of Weinrich et al (Eur. J. Org. Chem., 2017, 491).

### Step 2: Synthesis of 7-(diethylamino)-2-oxo-2H-chromen-4-yl)methyl methacrylate (PE-3B)

In a flame-dried flask, PE-3A (1.20 grams (g), 4.90 mmol) was dissolved in anhydrous THF (25 mL) along with triethylamine (2.0 mL, 41.3 mmol). Methacryloyl chloride (0.75 mL, 7.7 mmol) was added dropwise at 0° C. over 10 min. After stirring for 4 h at room temperature, the reaction mixture was filtered and most of the THF solvent removed by rotary evaporation. The residue was dissolved in dichloromethane and washed three times with a saturated aqueous K₂CO₃ solution. The organic phase was separated, dried over magnesium sulfate, filtered and evaporated to dryness. Finally, PE-3B was obtained after dissolving it in the minimum amount of CH₂Cl₂ and precipitating it in hexane.

### Step 3: Synthesis of Polymer PE-3C

Prior to use, N,N-dimethylaminoethyl methacrylate (DMAEMA) was added into a vial with inhibitor removers (MilliporeSigma), allowed to sit for 1 min and then syringed out. Then, a vial fitted with a septum was loaded with azobis(isobutyronitrile) (AIBN, 6 mg, 0.0365 mmol), PE-3B (337 mg, 1.07 mmol), DMAEMA (0.18 mL, 1.07 mmol) and anhydrous, deoxygenated toluene (8 mL). The reaction mixture was sparged with argon for 30 min and then stirred at 65° C. overnight. After 16 h, the reaction mixture was cooled, concentrated, and precipitated from CHCl₃ into hexanes three times to give the polymer PE-3C as a yellow powder.

### Preparative Example 4

### Preparation of Polycation and Polyanion Solutions

The compositions of the polycation and polyanion solutions described above are shown in Table 3.

TABLE 3
Compositions of Polycation and Polyanion Solutions

| | POLYELECTROLYTE SOLUTIONS | | | | | |
|---|---|---|---|---|---|---|
| COMPONENT | PE-4A | PE-4B | PE-4C | PE-4D | PE-4E | PE-4F |
| PE-2, g | 0.3 | | | | | |
| PE-3, g | | 0.075 | | | | |
| 0.5N HCl, g | | 150 | | | | |
| DMF, g | 149.6 | | | | | |
| SANCURE 20072 | | | | 18.52 | | |
| stock solution (27 | | | | | | |
| wt. %), g | | | | | | |
| NaCl, g | | | 2.92 | 5.84 | 1.46 | 1.46 |
| PSS stock solution | | | 3.33 | | | |
| (30 wt. %), g | | | | | | |
| p-toluenesulfonic | 0.125 | | | | | |
| acid monohydrate, g | | | | | | |
| CAB-O-JET 250C | | | | | 24.83 | |
| (10.07 wt. % stock | | | | | | |
| solution), g | | | | | | |
| CAB-O-JET 200 | | | | | | 24.84 |
| (20.13 wt. % stock | | | | | | |
| solution), g | | | | | | |
| Pluronic L92 | | | | 5 | | 5 |
| stock solution (10 | | | | | | |
| wt. %), g | | | | | | |
| Deionized water, g | | | 493.8 | 470.6 | 473.2 | 468.7 |

### General Method for Fabricating Layer-by-Layer (LBL) Coatings

The layer-by-layer constructions were prepared on glass (FISHERBRAND plain microscope slides, precleaned, 25×75×1 mm, catalog no.: 12-550-A3), PET film (3M Company, 2.4 mil thick, LOT: G120036F23) and PE-1. For the coatings prepared on glass, the substrates were initially rinsed with isopropyl alcohol, dried with nitrogen and plasma cleaned for 5 min. The glass slide was then mounted on the sample holder of a robotic dip coater like the system reported in Gamboa, et al, Review of Scientific Instruments 51, 036103 (2010). The automatic dip coater can be programmed to alternately immerse the substrate in the polycation and polyanion solutions. The coater was equipped with spray nozzles to rinse the substrates with DI water immediately after immersion in a coating solution and separate nozzles with compressed air to dry the substrates. The total dwell time for each immersion was 24 seconds. The glass slide was initially coated with a photodegradable LbL coating formulation. The mounted substrate was immersed in one of the polycation solutions (PE-4A or PE-4B), rinsed with deionized (DI) water and dried. The glass slide was then dipped in PE-4C, rinsed with DI water and dried. This sequence, which corresponds to 1 bilayer, was repeated until the desired number of bilayers were deposited. The resulting LbL coating is denoted by (Polycation/Polyanion)ₙ, where n is the number of bilayers.

A second stack of layer-by-layer coatings with carbon black was deposited on top of the photodegradable LbL coating using the robotic dip coater according to the following procedure.

The glass slide with photodegradable LbL was immersed in PE-4D, rinsed with DI water and dried. It was then submerged in PE-4F, rinsed with DI water and dried. This sequence was repeated until 6 bilayers of SC72 (from PE-4D) and COJ200 (from PE-4F) were achieved.

On the other hand, to prepare a sample on PET or PE-1, a sheet of polymer film was cut into a 4″×4″ (10.2 centimeters (cm)×10.2 cm) piece and adhered at the edges on a 4″×4.75″ (10.2 cm×12.0 cm) glass plate with epoxy (Scotch-Weld epoxy adhesive obtained as DP100 CLEAR, 3M Company, St. Paul, MN, USA). The substrate was cleaned with a delicate task wipe wet with isopropyl alcohol and corona treated by hand using a BD-20AC Laboratory Corona Treater (Electro-Technic Products, Chicago, IL, USA). Then, the robotic dip coater was used to coat 1-10 bilayers of a photodegradable LbL coating and 6 bilayers of the carbon black LbL coating as defined above.

### General Method of Light-Induced Delamination

The layer-by-layer constructions on various transparent substrates were irradiated with light (irradiance and LED peak wavelength as specified in the examples) through the backside (glass slide or polymer substrate) of the sample. After light exposure, the samples were exposed to developing conditions, which is typically a basic aqueous washing solution, rinsed with distilled water and dried with compressed nitrogen. LEDs used in the examples: (365 and 395 nm UV-LED heads for OMNICURE AC475, Excelitas Technologies, Mississauga, ON, Canada).

### EXAMPLES

### Examples 1 to 2 and Comparative Examples 1 to 2

### LbL Coating Deposition on Glass Substrates

Example 1 was made according to the General Method for Fabricating Layer-by-Layer Coatings, using the specific parameters in Table 4. Example 2 was also made according to the General Method for Fabricating Layer-by-Layer Coatings, using the specific parameters in Table 4, however, the additional COJ250C deposition was done by immersing the glass slide coated with 10.5 bilayers of PE-2 and PE-4C in PE-4E for 1 min, rinsed with DI water and dried with nitrogen.

TABLE 4
Coating conditions for Examples (EX) 1 and
2 and Comparative Examples (CE) 1 and 2.

| | | Photodegradable Coatings | | | Pigment Coatings | | |
|---|---|---|---|---|---|---|---|
| | | | | Number | | Number | UV |
| | | Polycation | Polyanion | of | Polyanion | of | Irradiation |
| Sample | Substrate | Solution | Solution | Bilayers | Solution | Bilayers | (Yes/No) |
| EX 1 | Glass | PE-2 | PE-4C | 10 | NA | NA | Yes |
| CE 1 | Glass | PE-2 | PE-4C | 10 | NA | NA | No |
| EX 2 | Glass | PE-2 | PE-4C | 10.5* | PE-4E | 0.5** | Yes |
| CE 2 | Glass | PE-2 | PE-4C | 10.5* | PE-4E | 0.5** | No |

*Signifies 11 layers of polycation coating and 10 layers of polyanion coating
**Signifies one dip coat of CAB-O-JET solution (PE-4E) as the final step.

### Photocleavage of a Pyrenemethyl Group Under UV Irradiation on Glass (Example 1 and Comparative Example 1)

Example 1 was irradiated with UV light from the Excelitas OmniCure AC475 (365 nm, 75% power at 2″ distance, approx. 855 mW/cm²) with increasing exposure times and washes. The degree of photodegradation was monitored using a Cary 60 UV-Vis Spectrophotometer (Agilent Technologies, Santa Clara, CA, USA). Table 5 presents selected data from the UV-vis absorbance spectra of Example 1 before and after irradiation and subsequent rinsing in 0.1 M NaHCO₃. As the irradiation time was increased (5 sec, then 40 sec, then 45 sec) with subsequent 0.1M NaHCO₃ washings in between light exposures, the characteristic absorbance peaks of pyrene between 320-375 nm gradually diminished. Meanwhile, Comparative Example 1 was prepared and coated similar to Example 1 but was only exposed to the washing sequence (no light exposure), which resulted in minimal changes to the UV-vis spectrum (Table 6).

TABLE 5
UV-Visible Spectroscopy Analysis of Example 1

| | Total # of | | |
|---|---|---|---|
| Irradiation | Wash | Absorbance Peak 1 | Absorbance Peak 2 |
| Conditions | Cycles | (349 nm) | (333 nm) |
| 365 nm, 0 sec | 0 | 0.154 | 0.132 |
| 365 nm, 5 sec | 1 | 0.125 | 0.107 |
| 365 nm, 45 | 2 | 0.044 | 0.040 |
| sec | | | |
| 365 nm, 90 | 3 | 0.001 | 0.002 |
| sec | | | |

TABLE 6
UV-Visible Spectroscopy Analysis of Comparative Example 1

| Irradiation | Total # of | Absorbance Peak 1 | Absorbance |
|---|---|---|---|
| Conditions | Wash Cycles | (349 nm) | Peak 2 (333 nm) |
| NA | 0 | 0.152 | 0.129 |
| NA | 1 | 0.138 | 0.118 |
| NA | 2 | 0.134 | 0.114 |
| NA | 3 | 0.134 | 0.114 |

### Binding and On-Demand Release of Anionic Species (Example 2 and Comparative Example 2)

Example 2 was irradiated with UV light from the Excelitas OmniCure AC475 (365 nm, 75% power at 2″ distance, approx. 855 mW/cm²) with increasing exposure times and washes. Table 7 presents the UV-vis absorbance spectra of Example 2 after irradiation and subsequent rinsing in 0.1 M NaHCO₃ for 5 minutes. As the irradiation time was increased, the characteristic absorbance peaks of pyrene (320-375 nm) and the pigment (550-740 nm) gradually diminished. Comparative Example 2 was only exposed to the washing sequence (3 washes in 0.1 M NaHCO₃ of 5 minutes each with no light exposure) and resulted in minimal changes to the UV-vis spectrum (Table 8).

TABLE 7
UV-Visible Spectroscopy Analysis of Example 2.

| | Total # | Absorbance | Absorbance | Absorbance | Absorbance |
|---|---|---|---|---|---|
| Irradiation | of Wash | Peak 1 (700 | Peak 2 (611 | Peak 3 (349 | Peak 4 (333 |
| Conditions | Cycles | nm) | nm) | nm) | nm) |
| 365 nm, 0 | 0 | 0.00386 | 0.00462 | 0.172 | 0.147 |
| sec | | | | | |
| 365 nm, 60 | 1 | 0.00221 | 0.00289 | 0.043 | 0.039 |
| sec | | | | | |
| 365 nm, | 2 | 0.00085 | 0.00034 | 0.003 | 0.003 |
| 120 sec | | | | | |

TABLE 8
UV-Visible Spectroscopy Analysis of Comparative Example 2.

| | | Absorbance | Absorbance | Absorbance | Absorbance |
|---|---|---|---|---|---|
| Irradiation | Washing | Peak 1 (700 | Peak 2 (611 | Peak 3 (349 | Peak 4 (333 |
| Conditions | Sequence(S) | nm) | nm) | nm) | nm) |
| NA | 0 | 0.00592 | 0.00683 | 0.178 | 0.153 |
| NA | 1 | 0.00694 | 0.00820 | 0.174 | 0.151 |
| NA | 2 | 0.00678 | 0.00785 | 0.173 | 0.150 |
| NA | 3 | 0.00684 | 0.00803 | 0.174 | 0.151 |

### Examples 3 to 4 and Comparative Examples 3 to 5

### Creation of LbL Coatings on Glass Substrates

Examples 3 and 4 and Comparative Examples 3, 4, and 5 were made according to the General Method for Fabricating Layer-by-Layer Coatings, using the specific parameters in Table 9.

TABLE 9
Coating Conditions for Examples (EX) 3 and 4
and Comparative Examples (CE) 3, 4, and 5.

| | | Photodegradable Coating | | | Carbon Black Coating | | |
|---|---|---|---|---|---|---|---|
| | | | | Number | | | Number |
| | | Polycation | Polyanion | of | Polycation | Polyanion | of |
| Sample | Substrate | Solution | Solution | Bilayers | Solution | Solution | Bilayers |
| EX 3 | Glass | PE-4B | PE-4C | 10 | PE-4D | PE-4F | 6 |
| EX 4 | Glass | PE-4B | PE-4C | 5 | PE-4D | PE-4F | 6 |
| CE 3 | Glass | — | — | — | PE-4D | PE-4F | 6 |
| CE 4 | Glass | PE-4B | PE-4C | 2 | PE-4D | PE-4F | 6 |
| CE 5 | Glass | PE-4B | PE-4C | 1 | PE-4D | PE-4F | 6 |

### Photopatterning of Carbon Black Coatings on Photodegradable LbL Coatings Glass Substrates

A photomask in the shape of one circle was prepared on aluminum foil by a paper punch.

Example 3 was placed in a water bath for 1 min, dried with compressed air, placed under the Excelitas OmniCure AC475 UV-LED (with the carbon black side facing down), covered with the circular photomask and exposed to UV light (395 nm, 30s, 20%, 2″ distance, approx. 386 mW/cm²). After irradiation, the sample was placed in a glass vial filled with the developer solution (0.1 M NaHCO₃) for 10 min. The vial was subsequently subjected to ultrasonication for 1 min, the sample taken out of the vial, rinsed with water and dried under a stream of compressed nitrogen.

This resulted in delamination in the shape of the photomask.

Example 4 was placed in a water bath for 1 min, dried with compressed air, placed under the Excelitas OmniCure AC475 UV-LED (with the carbon black side facing down), covered with the circular photomask and exposed to UV light (395 nm, 30s, 20%, 2″ distance, approx. 386 mW/cm²). After irradiation, the sample was placed in a glass vial filled with the developer solution (0.1 M NaHCO₃) for 10 min. The vial was subsequently subjected to ultrasonication for 1 min, the sample taken out of the vial, rinsed with water and dried under a stream of compressed nitrogen.

This resulted in delamination in the shape of the photomask.

Results of the area-selective delamination and the comparative examples are summarized in Table 10.

Comparative Examples 3, 4, and 5 were placed in a water bath for 1 min, dried with compressed air, placed under the Excelitas OmniCure AC475 UV-LED (with the carbon black side facing down), covered with the circular photomask and exposed to UV light (395 nm, 30s, 20%, 2″ distance, approx. 386 mW/cm²). After irradiation, the samples were placed in a glass vial filled with the developer solution (0.1 M NaHCO₃) for 10 min. The vials were subsequently subjected to ultrasonication for 1 min, the samples taken out of the vial, rinsed with water and dried under a stream of compressed nitrogen. No delamination was observed. The results were also summarized in Table 10.

TABLE 10
Results of Photopatterning Experiments on Examples
3 and 4 and Comparative Examples 3, 4, and 5.

| | IRRADIATION | AREA-SELECTIVE |
|---|---|---|
| EXAMPLE | CONDITIONS | DELAMINATION |
| Example 3 | 365 nm, 30 sec | Yes |
| Example 4 | 365 nm, 30 sec | Yes |
| Comparative Example 3 | 365 nm, 30 sec | No |
| Comparative Example 4 | 365 nm, 30 sec | No |
| Comparative Example 5 | 365 nm, 30 sec | No |

### Examples 5 to 7 and Comparative Examples 6 to 7

### Fabrication of LbL Coatings on Polymer Film Samples

Examples 5, 6, and 7 and Comparative Examples 6 and 7 were made according to the General Method for Fabricating Layer-by-Layer Coatings, using the specific parameters in Table 11.

TABLE 11
Coating Conditions for Examples (EX) 5 to
7 and Comparative Examples (CE) 6 and 7.

| | | Photodegradable Coatings | | | Carbon Black Coatings | | |
|---|---|---|---|---|---|---|---|
| | | | | Number | | | Number |
| | | Polycation | Polyanion | of | Polycation | Polyanion | of |
| Sample | Substrate | Solution | Solution | Bilayers | Solution | Solution | Bilayers |
| EX 5 | PET | PE-4B | PE-4C | 10 | PE-4D | PE-4F | 6 |
| EX 6 | PET | PE-4B | PE-4C | 5 | PE-4D | PE-4F | 6 |
| EX 7 | PE-1 | PE-4B | PE-4C | 10 | PE-4D | PE-4F | 6 |
| CE 6 | PET | — | — | — | PE-4D | PE-4F | 6 |
| CE 7 | PET | PE-4B | PE-4C | 2 | PE-4D | PE-4F | 6 |

### Photopatterning of Carbon Black Coatings on Photodegradable LbL Coatings—Polymer Film Samples

A photomask in the shape of a circle was prepared on aluminum foil by a paper punch.

Examples 5, 6, and 7 were placed under Excelitas OmniCure AC475 UV-LED (with the carbon black side facing down), covered with the circular photomask and exposed to UV light (395 nm, 30 s, 20%, 2″ distance, approx. 386 mW/cm²). After irradiation, the sample was placed in a glass vial filled with the developer solution (0.1 M NaHCO₃) for 10 min. The vial was subsequently subjected to ultrasonication for 10 min, the sample taken out of the vial, rinsed with water and dried under a stream of compressed nitrogen. This resulted in delamination in the shape of the photomask. The results are summarized in Table 12.

Comparative Examples 6 and 7 were placed under the Excelitas OmniCure AC475 UV-LED (with the carbon black side facing down), covered with the circular photomask and exposed to UV light (395 nm, 30s, 20%, 2″ distance, approx. 386 mW/cm²). After irradiation, the samples were placed in a glass vial filled with the developer solution (0.1 M NaHCO₃) for 10 min. The vial was subsequently subjected to ultrasonication for 10 min, the sample taken out of the vial, rinsed with water and dried under a stream of compressed nitrogen. No delamination was observed. The results were also summarized in Table 12.

TABLE 12
Results of Photopatterning Experiments on Examples
5 to 7 and Comparative Examples 6 and 7.

| | IRRADIATION | AREA-SELECTIVE |
|---|---|---|
| EXAMPLE | CONDITIONS | DELAMINATION |
| Example 5 | 365 nm, 30 sec | Yes |
| Example 6 | 365 nm, 30 sec | Yes |
| Example 7 | 365 nm, 30 sec | Yes |
| Comparative Example 6 | 365 nm, 30 sec | No |
| Comparative Example 7 | 365 nm, 30 sec | No |

Foreseeable modifications and alterations of this invention will be apparent to those skilled in the art without departing from the scope and spirit of this invention. This invention should not be restricted to the embodiments that are set forth in this application for illustrative purposes.

1. An article comprising:
a) a substrate; and
b) a coating disposed on a major surface of the substrate, the coating comprising one or more polyelectrolytes, a photocleavable polymer, and optionally a light absorbing material, wherein the light absorbing material is present and/or the photocleavable polymer comprises a polymer of any of Formula I, Formula II, and/or Formula III: 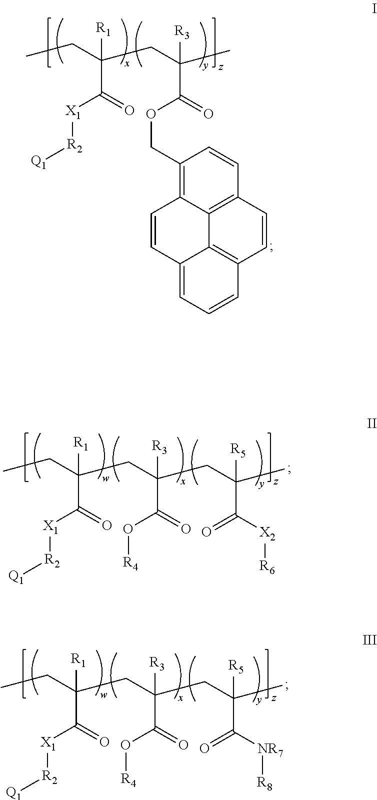
wherein R₁ is independently selected from H or methyl; R₂ is independently selected from an alkylene group or a heteroalkylene group; Q₁ is independently selected from an amino group selected from a primary amino group, secondary amino group, tertiary amino group, quaternary amino group, or a salt thereof; R₃ is independently selected from H or methyl; X₁ is O or NH; R₄ is independently selected from a photocleavable group selected from the group consisting of arylmethyl, coumarin-4-ylmethyl, nitroaryl, and arylcarbonylmethyl; R₅ is independently selected from H or methyl; X₂ is O or NH; R₆ is independently selected from OH or a heteroalkylene group; R₇ is H or methyl; R₈ is H or methyl; and each of w, x, y, and z is a designation of a repeat unit.

2. The article of claim 1, wherein the light absorbing material is present.

3. The article of claim 1, wherein the light absorbing material is present and comprises a pigment.

4. The article of claim 2, wherein the pigment comprises carbon black.

5. The article of claim 1, wherein the coating comprises a first plurality of bi-layers of polycation/polyanion, wherein some or all of the polycation comprises the photocleavable polymer.

6. The article of claim 5, wherein the light absorbing material is present in or on the first plurality of bi-layers.

7. The article of claim 6, wherein the light absorbing material is present in a layer disposed on the first plurality of bi-layers.

8. The article of claim 5, wherein the coating further comprises a second plurality of bi-layers of polycation/polyanion, wherein the polyanion of the second plurality of bi-layers comprises the light absorbing material.

9. The article of claim 1, wherein the light absorbing material is present and the photocleavable polymer comprises a polymer of Formula IV: 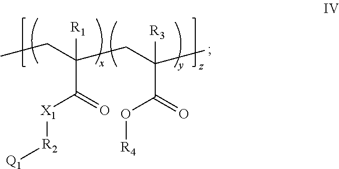
wherein R₁ is H or methyl; R₂ is an alkylene group or a heteroalkylene group; Q₁ is an amino group selected from a primary amino group, secondary amino group, tertiary amino group, quaternary amino group, or a salt thereof, R₃ is H or methyl; X₁ is O or NH; R₄ is a photocleavable group selected from the group consisting of arylmethyl, coumarin-4-ylmethyl, nitroaryl, and arylcarbonylmethyl; and each of x, y, and z is a designation of a repeat unit.

10. The article of claim 1, wherein the photocleavable polymer comprises a polymer of Formula I: 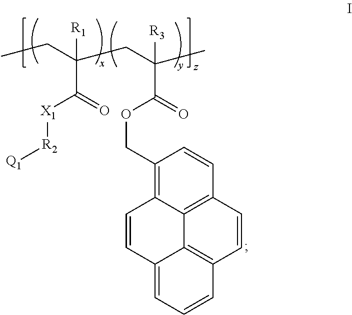
wherein R₁ is H or methyl; R₂ is an alkylene group or a heteroalkylene group; Q₁ is an amino group selected from a primary amino group, secondary amino group, tertiary amino group, quaternary amino group, or a salt thereof, R₃ is H or methyl; X₁ is O or NH; and each of x, y, and z is a designation of a repeat unit.

11. The article of claim 1, wherein the photocleavable polymer comprises a polymer of Formula II: 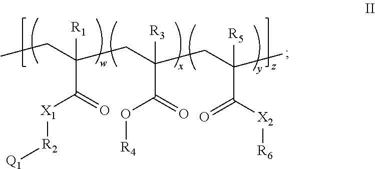
wherein R₁ is H or methyl; R₂ is an alkylene group or a heteroalkylene group; Q₁ is an amino group selected from a primary amino group, secondary amino group, tertiary amino group, quaternary amino group, or a salt thereof, R₃ is H or methyl; X₁ is O or NH; R₄ is a photocleavable group selected from the group consisting of arylmethyl, coumarin-4-ylmethyl, nitroaryl, and arylcarbonylmethyl; R₅ is H or methyl; X₂ is O or NH; R₆ is OH or a heteroalkylene group; and each of w, x, y, and z is a designation of a repeat unit.

12. The article of claim 1, wherein the photocleavable polymer comprises a polymer of Formula III: 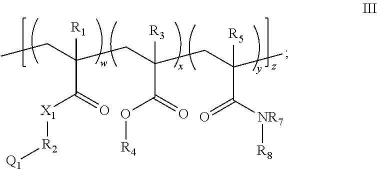
wherein R₁ is H or methyl; R₂ is an alkylene group or a heteroalkylene group; Q₁ is an amino group selected from a primary amino group, secondary amino group, tertiary amino group, quaternary amino group, or a salt thereof, R₃ is H or methyl; X₁ is O or NH; R₄ is a photocleavable group selected from the group consisting of arylmethyl, coumarin-4-ylmethyl, nitroaryl, and arylcarbonylmethyl; R₅ is H or methyl; R₆ is OH or a heteroalkylene group; R₇ is H or methyl; R₈ is H or methyl; and each of w, x, y, and z is a designation of a repeat unit.

13. The article of claim 1, wherein the photocleavable polymer comprises a polymer of Formula V: 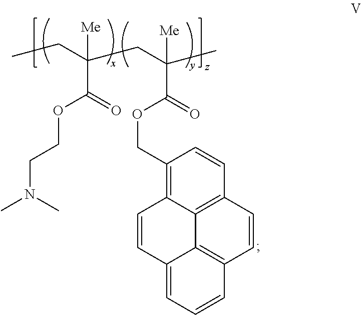
wherein each of x, y, and z is a designation of a repeat unit.

14. The article of claim 1, wherein the coating is present on the substrate in a pattern.

15. A method of making an article, the method comprising:
a) applying a coating to a major surface of a substrate, the coating comprising one or more polyelectrolytes, a photocleavable polymer, and optionally a light absorbing material, wherein the light absorbing material is present and/or the photocleavable polymer comprises a polymer of any of Formula I, Formula II, and/or Formula III: 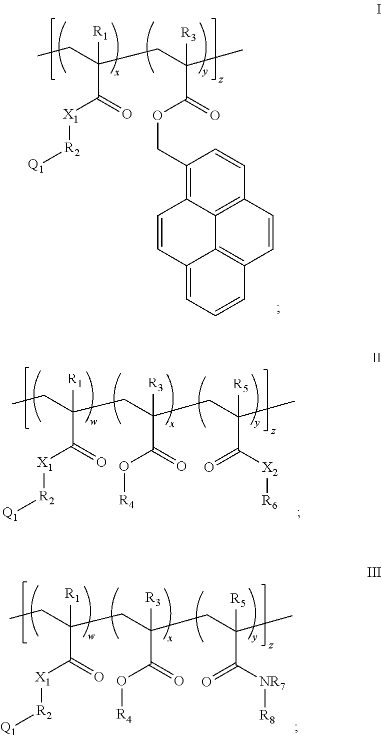
wherein R₁ is independently selected from H or methyl; R₂ is independently selected from an alkylene group or a heteroalkylene group; Q₁ is independently selected from an amino group selected from a primary amino group, secondary amino group, tertiary amino group, quaternary amino group, or a salt thereof, R₃ is independently selected from H or methyl; X₁ is O or NH; R₄ is independently selected from a photocleavable group selected from the group consisting of arylmethyl, coumarin-4-ylmethyl, nitroaryl, and arylcarbonylmethyl; R₅ is independently selected from H or methyl; X₂ is O or NH; R₆ is independently selected from OH or a heteroalkylene group; R₇ is H or methyl; R₈ is H or methyl; and each of w, x, y, and z is a designation of a repeat unit.

16. The method of claim 15, wherein the coating is applied by applying a first layer having a first bonding group to the substrate and applying a second layer having a second bonding group to the first layer, wherein the second bonding group is complementary to the first bonding group.

17. The method of claim 15, wherein the coating is applied by layer-by-layer assembly.

18. The method of claim 15, further comprising:
covering portions of the coating with a photomask;
irradiating the masked article with light; and
rinsing the irradiated article to remove the uncovered portions of the coating, thereby providing an article in which the coating is present on the substrate in a pattern.

19. The method of claim 15, further comprising:
irradiating the article with spatioselective light; and
rinsing the irradiated article to remove the irradiated portions of the coating, thereby providing an article in which the coating is present on the substrate in a pattern.

20. The method of claim 18, wherein the irradiating comprises directing the light through the substrate.
